(19) United States
(12) Patent Application Publication
(10) Pub. No.: US 2026/0293359 A1
(43) Pub. Date: Sep. 24, 2026

(54) SEMICONDUCTOR PACKAGE AND METHOD FOR PRODUCING SEMICONDUCTOR PACKAGE

(71) Applicant: SONY SEMICONDUCTOR SOLUTIONS CORPORATION, KANAGAWA (JP)

(72) Inventor: HIROHITO MIYAZAKI, KANAGAWA (JP)

(21) Appl. No.: 19/473,593

(22) PCT Filed: Mar. 4, 2024
(86) PCT No.: PCT/JP2024/007953

§ 371 Date: Oct. 8, 2025

(30) Foreign Application Priority Data
Apr. 28, 2023 (JP) 2023-073940

(51) Int. Cl. H10F 39/95; H10F 39/00

(52) U.S. Cl. CPC H10F 39/95; H10F 39/011; H10F 39/804; H10F 39/8057; H10F 39/811

(57) ABSTRACT

To reduce the number of components of a mounting substrate in an electronic device including a semiconductor package having a cavity structure. The semiconductor package includes a semiconductor substrate, a first semiconductor chip, and a first component. In this semiconductor package, a frame portion is formed around a predetermined region in one surface of two surfaces of the semiconductor substrate when viewed from a direction perpendicular to the one surface. The first semiconductor chip is mounted on the predetermined region. The first component is mounted on a surface of the frame portion formed on the semiconductor substrate.

### TECHNICAL FIELD

The present technology relates to a semiconductor package. Specifically, the present disclosure relates to a semiconductor package including a cavity and a method for producing the semiconductor package.

### BACKGROUND ART

In the related art, in a semiconductor package such as a CMOS image sensor (CIS) package, a cavity structure has been used. For example, a semiconductor package has been proposed in which a cavity formed by a substrate and a frame surrounding a solid-state imaging element is sealed with glass (for example, see PTL 1). In this semiconductor package, a conductor is embedded in the frame, and one end of the conductor is connected to a fixing metal fitting.

CITATION LIST

### Patent Literature

PTL 1: WO 2017/090223

### SUMMARY OF INVENTION

### Technical Problem

In the above-described related art, by connecting the one end of the conductor in the frame to the fixing metal fitting, heat dissipation characteristics are intended to be improved. However, in the above-described related art, when a space for mounting a component such as a capacitor is insufficient on the semiconductor package side, the component cannot be mounted on the semiconductor package instead of a mounting substrate. Thus, it is difficult to reduce the number of components of the mounting substrate.

The present technology has been made in view of such circumstances, and in an electronic device including a semiconductor package having a cavity structure, it is an object to reduce the number of components of the mounting substrate.

### Solution to Problem

The present technology has been made to solve the above-described problems, and a first aspect thereof is a semiconductor package including a semiconductor substrate in which a frame portion is formed around a predetermined region in one surface of two surfaces when viewed from a direction perpendicular to the one surface, a first semiconductor chip mounted in the predetermined region, and a first component mounted on a surface of the frame portion. This brings about an effect that the number of components of the mounting substrate can be reduced.

In addition, in the first aspect, the frame portion may be a molded interconnect device (MID). This brings about an effect that wiring can be performed on the surface of the frame portion.

In addition, in the first aspect, the first component may be rectangular when viewed from a direction perpendicular to the surface of the frame portion, and the first component may be mounted at a position where a longitudinal direction of the first component is perpendicular or horizontal to an inner periphery of the frame portion. This brings about an effect of facilitating surface mounting of the components.

In addition, in the first aspect, a solder resist applied to a surface of the MID may be further included. This brings about an effect of improving reliability.

In addition, in the first aspect, the frame portion may cover the one surface of the semiconductor substrate and a side surface of the first semiconductor chip. This brings about an effect of suppressing occurrence of burrs at a substrate end.

In addition, in the first aspect, the frame portion may further cover at least a part of the other surface of the two surfaces of the semiconductor substrate. This brings about an effect of facilitating wiring on the other surface.

In addition, in the first aspect, a solder ball disposed on the other surface of the semiconductor substrate may be further included. This brings about an effect that the semiconductor package is connected to the mounting substrate.

In addition, in the first aspect, a glass, a light-shielding film that shields a part of the glass from light, and a second component with which a surface of the light-shielding film is provided may be further included. This brings about an effect of suppressing flare.

In addition, in the first aspect, the light-shielding film may be the MID. This brings about an effect that wiring can be performed on the surface of the light-shielding film.

In addition, in the first aspect, a second semiconductor chip mounted around the frame portion may be further included. This brings about an effect of improving the performance of the semiconductor package.

In addition, in the first aspect, the frame portion and the semiconductor substrate may be the MID. This brings about an effect that the frame portion and the semiconductor substrate are integrally molded.

In addition, in the first aspect, a recessed portion may be formed on a side surface of the frame portion, and the first component may be mounted in the recessed portion. This brings about an effect of facilitating mounting of the first component.

Further, a second aspect of the present technology is a producing method for a semiconductor package including a substrate producing procedure of preparing a semiconductor substrate in which a frame portion is formed around a predetermined region in one surface of two surfaces when viewed from a direction perpendicular to the one surface, and a component mounting procedure of mounting a first component on a surface of the frame portion. This brings about an effect that the number of components of the mounting substrate can be reduced.

In addition, in the second aspect, a cutting procedure of cutting a collective substrate including a plurality of semiconductor packages each provided with the first semiconductor chip, the frame portion, and the semiconductor substrate into individual semiconductor packages may be further included. This brings about an effect of improving producing efficiency.

In the substrate producing procedure of the second aspect, the frame portion and the semiconductor substrate may be connected to each other using solder. This brings about an effect of facilitating connection between the frame portion and the semiconductor substrate.

In the substrate producing procedure of the second aspect, the frame portion and the semiconductor substrate may be connected to each other by thermocompression bonding. This brings about an effect of facilitating connection between the frame portion and the semiconductor substrate.

### BRIEF DESCRIPTION OF DRAWINGS

FIG. 1 is a block diagram illustrating a configuration example of an electronic device according to a first embodiment of the present technology.

FIG. 2 is a cross-sectional view illustrating a configuration example of a semiconductor package according to the first embodiment of the present technology.

FIG. 3 is an example of a top view of a frame portion when components are connected in series in the first embodiment of the present technology.

FIG. 4 is an example of a top view of the frame portion when components are connected in parallel in the first embodiment of the present technology.

FIG. 5 is an example of a top view of the frame portion when components are connected in series and in parallel in the first embodiment of the present technology.

FIG. 6 is a block diagram illustrating a configuration example of the semiconductor package according to the first embodiment of the present technology.

FIG. 7 is a cross-sectional view illustrating a configuration example of the electronic device according to the first embodiment of the present technology.

FIG. 8 is views for explaining a producing method up to formation of the frame portion in the first embodiment of the present technology.

FIG. 9 is views for explaining a producing method up to mounting of the components in the first embodiment of the present technology.

FIG. 10 is views for explaining a producing method up to wire bonding in the first embodiment of the present technology.

FIG. 11 is views for explaining a producing method up to bonding of a seal glass in the first embodiment of the present technology.

FIG. 12 is examples of plan views of the frame portion before and after application of a solder resist in the first embodiment of the present technology.

FIG. 13 is graphs showing an example of long-term reliability before and after coating with the solder resist in the first embodiment of the present technology.

FIG. 14 is a flowchart showing an example of a producing method for the semiconductor package according to the first embodiment of the present technology.

FIG. 15 is a cross-sectional view illustrating a configuration example of a semiconductor package according to a second embodiment of the present technology.

FIG. 16 is views for explaining a producing method up to formation of the frame portion in the second embodiment of the present technology.

FIG. 17 is views for explaining a producing method up to mounting of the components in the second embodiment of the present technology.

FIG. 18 is views for explaining a producing method up to wire bonding in the second embodiment of the present technology.

FIG. 19 is views for explaining a producing method up to bonding of a seal glass in the second embodiment of the present technology.

FIG. 20 is an example of a cross-sectional view illustrating a configuration example of a semiconductor package according to a modification of the second embodiment of the present technology.

FIG. 21 is examples of a bottom view and a perspective view illustrating the semiconductor package according to the modification of the second embodiment of the present technology.

FIG. 22 is views for explaining a producing method up to formation of the frame portion in the modification of the second embodiment of the present technology.

FIG. 23 is views for explaining a producing method up to mounting of the components in the modification of the second embodiment of the present technology.

FIG. 24 is views for explaining a producing method up to wire bonding in the modification of the second embodiment of the present technology.

FIG. 25 is views for explaining a producing method up to bonding of a seal glass in the modification of the second embodiment of the present technology.

FIG. 26 is a cross-sectional view illustrating a configuration example of a semiconductor package according to a third embodiment of the present technology.

FIG. 27 is an example of a top view of a semiconductor package according to the third embodiment of the present technology.

FIG. 28 is views for explaining a producing method up to formation of the frame portion in the third embodiment of the present technology.

FIG. 29 is views for explaining a producing method up to mounting of the components in the third embodiment of the present technology.

FIG. 30 is views for explaining a producing method up to bonding of a seal glass in the third embodiment of the present technology.

FIG. 31 is views for explaining a producing method up to mounting of the components and solder balls in the third embodiment of the present technology.

FIG. 32 is an example of a cross-sectional view illustrating a semiconductor package according to a modification of the third embodiment of the present technology.

FIG. 33 is views for explaining a producing method according to a fourth embodiment of the present technology.

FIG. 34 is views for explaining a producing method according to a fifth embodiment of the present technology.

FIG. 35 is views for explaining a producing method according to a sixth embodiment of the present technology.

FIG. 36 is a cross-sectional view illustrating a configuration example of a semiconductor package according to a seventh embodiment of the present technology.

FIG. 37 is a cross-sectional view illustrating a configuration example of a semiconductor package according to an eighth embodiment of the present technology.

FIG. 38 is views for explaining a producing method up to application of a die bond material in the eighth embodiment of the present technology.

FIG. 39 is views for explaining a producing method up to application of a seal material in the eighth embodiment of the present technology.

FIG. 40 is views for explaining a producing method up to formation of solder balls in the eighth embodiment of the present technology.

FIG. 41 is a cross-sectional view illustrating a configuration example of a semiconductor package according to a ninth embodiment of the present technology.

FIG. 42 is views for explaining a producing method up to application of the die bond material in a tenth embodiment of the present technology.

FIG. 43 is views for explaining a producing method up to application of the seal material in the tenth embodiment of the present technology.

FIG. 44 is views for explaining a producing method up to formation of the solder balls in the tenth embodiment of the present technology.

FIG. 45 is a cross-sectional view illustrating a configuration example of a semiconductor package according to an eleventh embodiment of the present technology.

FIG. 46 is views for explaining a producing method up to application of the die bond material in the eleventh embodiment of the present technology.

FIG. 47 is views for explaining a producing method up to application of the seal material in the eleventh embodiment of the present technology.

FIG. 48 is views for explaining a producing method up to formation of the solder balls in the eleventh embodiment of the present technology.

FIG. 49 is a block diagram illustrating a schematic configuration example of a vehicle control system.

FIG. 50 is an explanatory view illustrating an example of an installation position of an imaging section.

### DESCRIPTION OF EMBODIMENTS

Hereinafter, modes (hereinafter, referred to as embodiments) for implementing the present technology will be described. The description will be made in the following order.
1. First Embodiment (an example of mounting components on a frame portion)
2. Second Embodiment (an example of mounting components on a frame portion including a substrate)
3. Third Embodiment (an example of mounting components on a light-shielding film and a frame portion)
4. Fourth Embodiment (an example of cutting a collective substrate and mounting components on a frame portion)
5. Fifth Embodiment (an example of mounting components on a frame portion and connecting the components to a substrate by soldering)
6. Sixth Embodiment (an example of mounting components on a frame portion and connecting the components to a substrate by thermocompression bonding)
7. Seventh Embodiment (an example of mounting components on a frame portion and providing a semiconductor chip also on the outer side of the frame portion)
8. Eighth Embodiment (an example of integrally molding a frame portion and a substrate and mounting a component on the frame portion)
9. Ninth Embodiment (an example of integrally molding a frame portion and a substrate and mounting a component in a recessed portion formed in the frame portion)
10. Tenth Embodiment (an example of mounting a component in a recessed portion formed in a frame portion)
11. Example of Application to Mobile Body

### 1. First Embodiment

### Configuration Example of Electronic Device

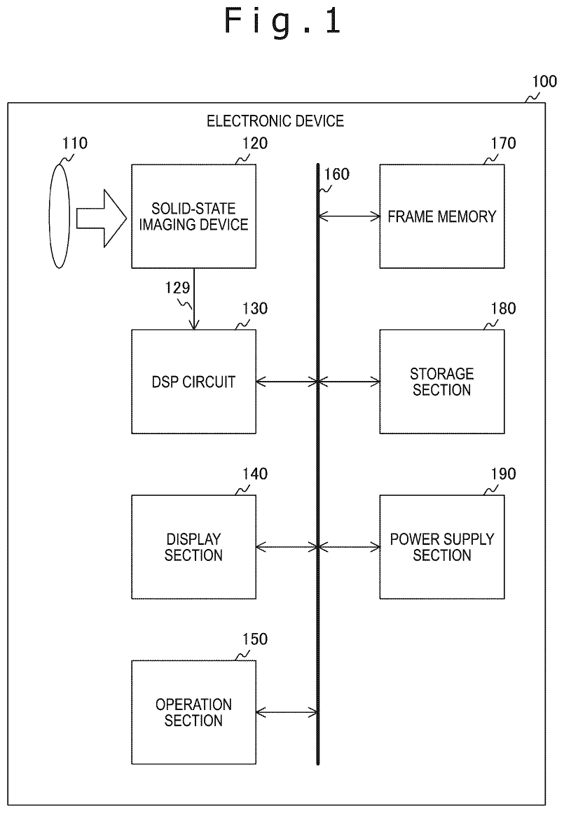

FIG. 1 is a block diagram illustrating a configuration example of an electronic device 100 according to the first embodiment of the present technology. The electronic device 100 is a device for imaging image data, and includes an optical section 110, a solid-state imaging element 120, and a digital signal processing (DSP) circuit 130. The electronic device 100 further includes a display section 140, an operation section 150, a bus 160, a frame memory 170, a storage section 180, and a power supply section 190. As the electronic device 100, for example, a smartphone, a personal computer, or a vehicle-mounted camera is assumed in addition to a digital camera such as a digital still camera.

The optical section 110 collects light from a subject and guides the light to the solid-state imaging element 120. The solid-state imaging element 120 generates image data by photoelectric conversion in synchronization with a vertical synchronization signal. Here, the vertical synchronization signal is a periodic signal of a predetermined frequency indicating the timing of imaging. The solid-state imaging element 120 supplies the generated image data to the DSP circuit 130.

The DSP circuit 130 executes predetermined signal processing on the image data from the solid-state imaging element 120. The DSP circuit 130 outputs the processed image data to the frame memory 170 or the like via the bus 160.

The display section 140 displays the image data. As the display section 140, for example, a liquid crystal panel or an organic electroluminescence (EL) panel is assumed. The operation section 150 generates an operation signal according to an operation of a user.

The bus 160 is a common path for the optical section 110, the solid-state imaging element 120, the DSP circuit 130, the display section 140, the operation section 150, the frame memory 170, the storage section 180, and the power supply section 190 to exchange data with each other.

The frame memory 170 holds the image data. The storage section 180 stores various pieces of data such as the image data. The power supply section 190 supplies power to the solid-state imaging element 120, the DSP circuit 130, the display section 140, and the like.

In the above-described configuration, for example, the solid-state imaging element 120 is mounted in a semiconductor package described later.

### Configuration Example of Semiconductor Package

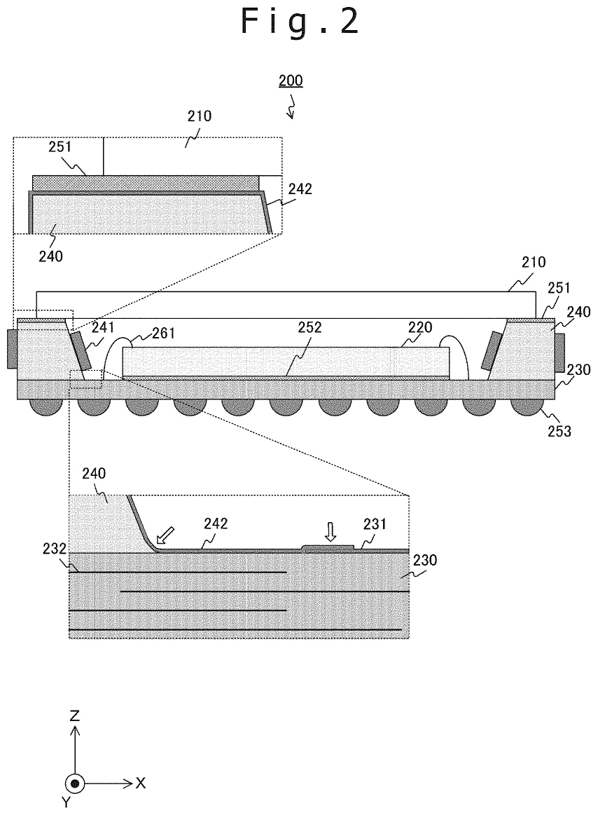

FIG. 2 is a cross-sectional view illustrating a configuration example of a semiconductor package 200 according to the first embodiment of the present technology. The semiconductor package 200 includes a seal glass 210, a sensor chip 220, a multilayer wiring substrate 230, and a frame portion 240. A chip that functions as the solid-state imaging element 120 in FIG. 1 is used as the sensor chip 220 in FIG. 2. The semiconductor package 200 may be referred to as a CIS package.

The sensor chip 220 is mounted on a predetermined region in one surface of the two surfaces of the multilayer wiring substrate 230 by wires 261, and a predetermined number of solder balls 253 are provided on the other surface. Hereinafter, a direction from the multilayer wiring substrate 230 to the sensor chip 220 is an “upward” direction. A predetermined axis parallel to an upper surface of the multilayer wiring substrate 230 is an “X-axis”, and a direction perpendicular to the upper surface is a “Z” axis. An axis perpendicular to the X-axis and the Z-axis is a “Y-axis”. FIG. 2 is a cross-sectional view as viewed from the Y-axis direction.

The multilayer wiring substrate 230 is a substrate including a plurality of conductor layers. The wiring line 232 is formed on each of the conductor layers. Further, a wiring line 231 is formed on an upper surface of the multilayer wiring substrate 230, and a predetermined number of solder balls 253 are formed on a lower surface of the multilayer wiring substrate 230. The multilayer wiring substrate 230 is an example of the semiconductor substrate described in the appended claims.

The sensor chip 220 generates image data by photoelectric conversion. The sensor chip 220 is bonded to a predetermined region on the upper surface of the multilayer wiring substrate 230 via a die bond material 252 and is electrically connected to the multilayer wiring substrate 230 by the wires 261. The sensor chip 220 is an example of the first semiconductor chip described in the appended claims.

The frame portion 240 is a member having a frame shape formed around the sensor chip 220 when viewed from the Z-axis direction, on the upper surface of the multilayer wiring substrate 230. As the frame portion 240, for example, an MID, which is a resin molded product provided with a wiring line 242 formed on the surface thereof, is used. A part of the wiring line 242 is formed along the upper surface of the multilayer wiring substrate 230, and one end of the wiring line 242 overlaps the wiring line 231 on the upper surface of the multilayer wiring substrate 230 and is electrically connected to the wiring line 231. An arrow on the right side of FIG. 2 indicates an overlapping portion, that is, a portion where the wiring lines 242 and 231 are connected to each other. In order to facilitate wiring from the frame portion 240 to the upper surface of the multilayer wiring substrate 230, a contour of a cross-sectional shape of the frame portion 240 preferably has an arc shape near a boundary between the frame portion 240 and the multilayer wiring substrate 230. A portion of an arrow on the left side of FIG. 2 indicates a portion where the arc shape is formed.

A predetermined number of components 241 can be mounted on a surface of the frame portion 240. As these components 241, passive components such as a capacitor and a resistor, and active components such as a transistor and a diode are assumed. The seal glass 210 is bonded to the upper surface of the frame portion 240 and the lower surface of the frame portion 240 is in contact with the multilayer wiring substrate 230, and thus the components 241 are mounted on side surfaces of the frame portion 240. The component 241 is an example of the first component described in the appended claims.

The seal glass 210 is bonded to the upper surface of the frame portion 240 via a seal material 251. A cavity, which is a space surrounded by the multilayer wiring substrate 230 and the frame portion 240, is sealed by the seal glass 210. The seal glass 210 is an example of the glass described in the appended claims.

In FIG. 2, the MID is provided as the frame portion 240 in the CIS package, but the MID may be provided in a semiconductor package other than the CIS package as long as the semiconductor package includes a cavity. For example, the MID may be provided as the frame portion 240 in a micro electro mechanical systems (MEMS) package.

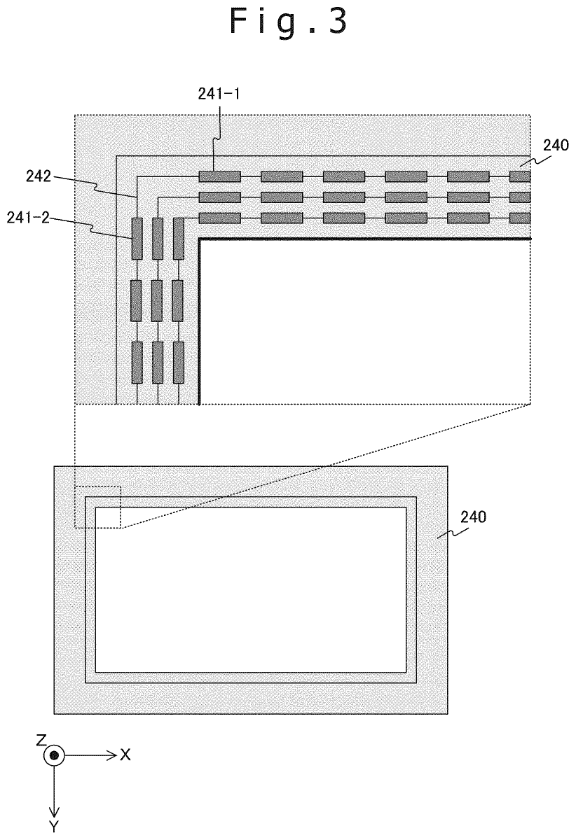

FIG. 3 is an example of a top view of the frame portion 240 when the components 241 are connected in series in the first embodiment of the present technology. FIG. 3 is a top view illustrating the frame portion 240 when viewed from the Z-axis direction. As illustrated in FIG. 3, the frame portion 240 is a member having a frame shape. On side surfaces on the inner side of the frame portion 240, a predetermined number of wiring lines 242 are wired along the inner periphery of the frame portion 240, for example. A predetermined number of components 241, such as components 241-1 and 241-2, are inserted in series into each of these wiring lines 242, for example.

When the component 241 is rectangular when viewed from the direction perpendicular to the surface of the frame portion 240, the components 241 are arrayed such that the longitudinal direction of the component 241 is horizontal to the inner periphery of the frame portion 240. A thick line in FIG. 3 indicates the inner periphery of the frame portion 240. For example, the longitudinal direction of the component 241-1 is horizontal to the X-axis along the inner periphery. The longitudinal direction of the component 241-2 is horizontal to the Y-axis along the inner periphery.

The connection and arrangement of the components 241 are not limited to those illustrated in FIG. 3.

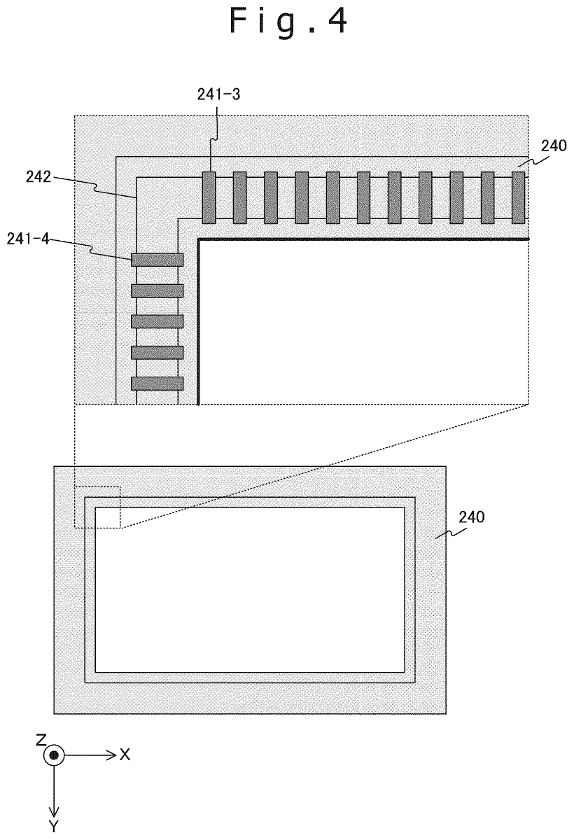

For example, as illustrated in FIG. 4, a predetermined number of components 241, such as components 241-3 and 241-4, may be connected in parallel. In FIG. 3, the components 241 are arrayed such that the longitudinal direction of the components 241 is perpendicular to the inner periphery of the frame portion 240. For example, the longitudinal direction of the component 241-3 is perpendicular to the X-axis along the inner periphery. The longitudinal direction of the component 241-4 is perpendicular to the Y-axis along the inner periphery.

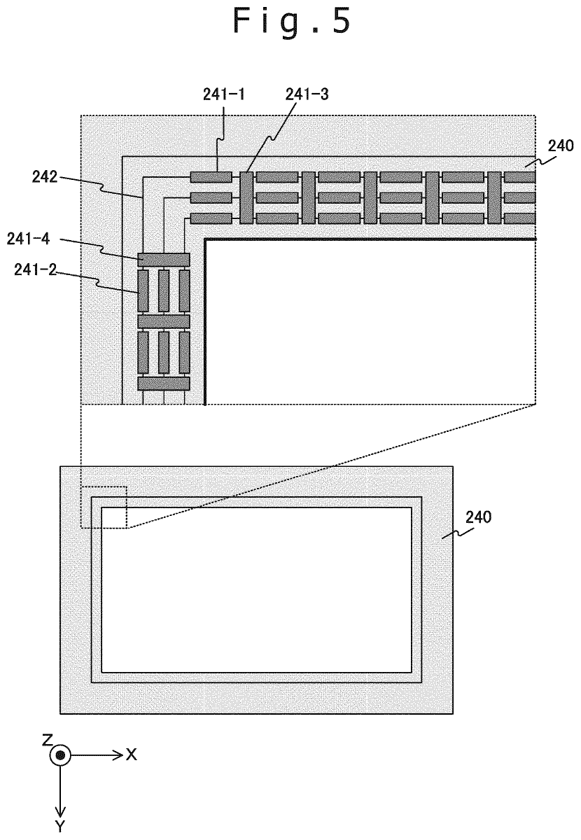

As illustrated in FIG. 5, the components 241-1, 241-2, and the like may be connected in series, and the components 241-3, 241-4, and the like may be connected in parallel. In FIG. 5, the components 241 are arrayed such that the longitudinal direction of the components 241 is horizontal or perpendicular to the inner periphery of the frame portion 240. For example, the longitudinal direction of the component 241-1 is horizontal to the X-axis along the inner periphery. The longitudinal direction of the component 241-2 is horizontal to the Y-axis along the inner periphery. Further, the longitudinal direction of the component 241-3 is perpendicular to the X-axis along the inner periphery. The longitudinal direction of the component 241-4 is perpendicular to the Y-axis along the inner periphery.

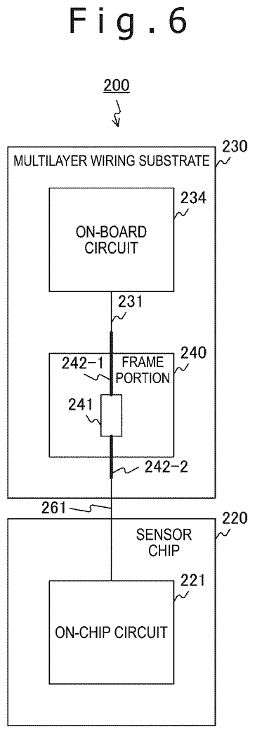

FIG. 6 is a block diagram illustrating a configuration example of the semiconductor package 200 according to the first embodiment of the present technology. The multilayer wiring substrate 230 includes an on-board circuit 234. The on-board circuit 234 is connected to the wiring line 231 on the upper surface of the multilayer wiring substrate 230.

The sensor chip 220 includes an on-chip circuit 221. In the on-chip circuit 221, circuits for generating image data, such as a vertical drive circuit, pixels, a logic circuit, a digital to analog converter (DAC), and an analog to digital converter (ADC), are disposed. The on-chip circuit 221 is connected to the wire 261.

Here, the wiring line 242 on the MID includes wiring lines 242-1 and 242-2. The wiring line 242-1 connects the component 241 and the wiring line 231 on the multilayer wiring substrate 230 to each other. The wiring line 242-2 connects the wire 261 for wire bonding and the component 241 to each other. The thick lines in FIG. 6 indicate the wiring lines 242-1 and 242-2.

By using the MID as the frame portion 240, as illustrated in FIG. 6, the component 241 between the sensor chip 220 and the multilayer wiring substrate 230 can be mounted on the frame portion 240.

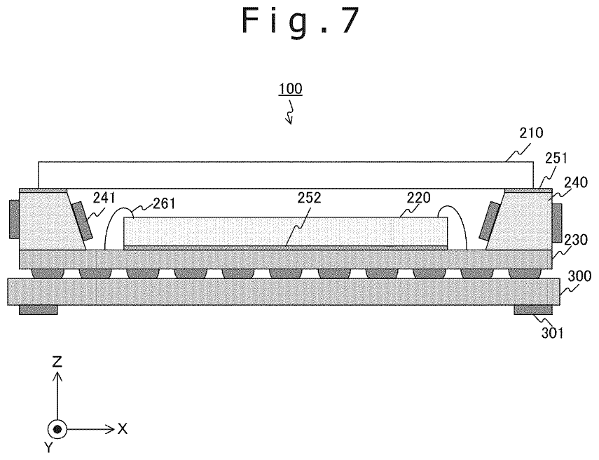

FIG. 7 is a cross-sectional view illustrating a configuration example of the electronic device 100 according to the first embodiment of the present technology. The electronic device 100 includes the semiconductor package 200 and a mounting substrate 300. A lower surface of the semiconductor package 200 is connected to the mounting substrate 300. Various circuits such as the DSP circuit 130 (not illustrated) are provided on the mounting substrate 300. Components 301 such as a capacitor are mounted on the lower surface of the mounting substrate 300.

As described above, by mounting the components 241 also on the side surfaces of the frame portion 240, the number of components of the mounting substrate 300 can be reduced accordingly. By reducing the number of components, the electronic device 100 can be reduced in size as compared with a case where the components 241 are not mounted on the frame portion 240. Further, by reducing the number of components of the mounting substrate 300, a space for providing a mechanism for heat dissipation such as a heat dissipation plate can be secured on the mounting substrate 300. The heat dissipation characteristics can be improved by mounting the heat dissipation plate or the like.

### Method for Producing Semiconductor Package

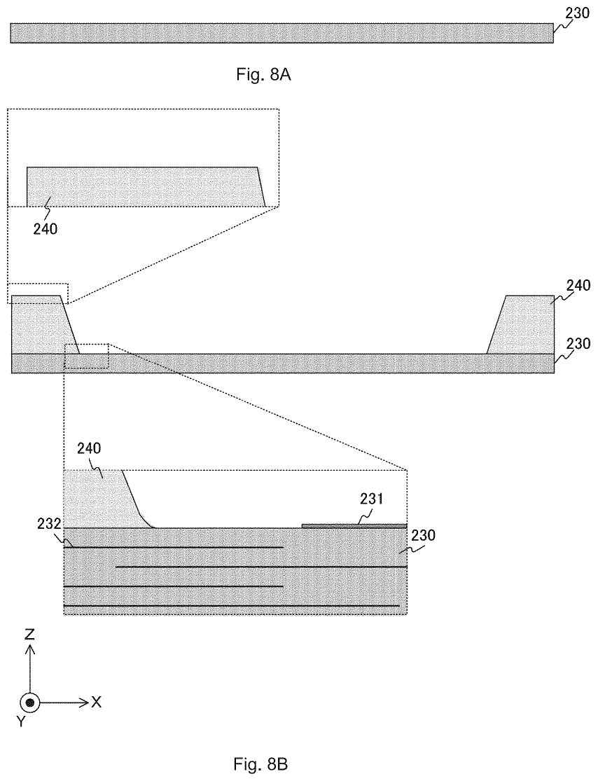

Next, a producing method for the semiconductor package 200 will be described with reference to FIGS. 8 to 11. First, as illustrated in FIG. 8a, a multilayer wiring substrate 230 is prepared. Subsequently, as illustrated in FIG. 8b, the frame portion 240 is formed on the upper surface of the multilayer wiring substrate 230.

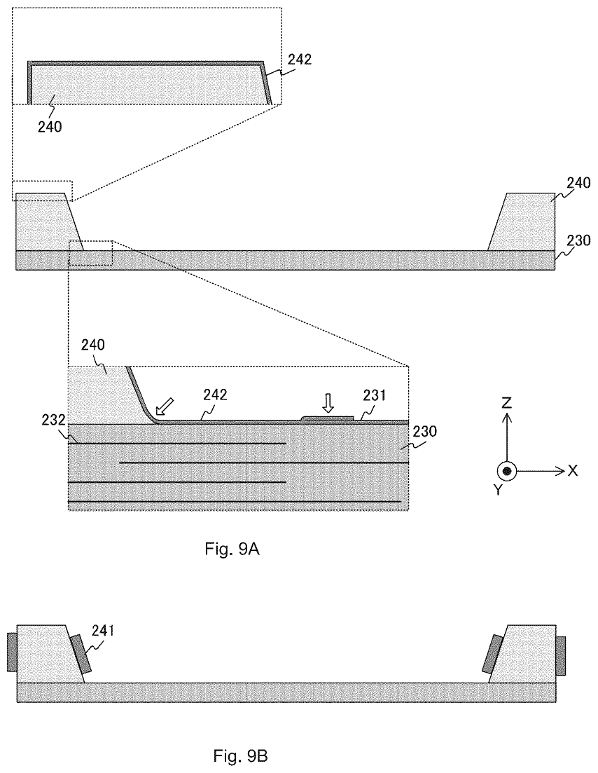

Then, as illustrated in FIG. 9a, the wiring line 242 is formed on the surface of the frame portion 240 by plating processing. During the plating processing, the wiring line 242 is formed so as to partially overlap the wiring line 231 on the upper surface of the multilayer wiring substrate 230, and is electrically connected to the wiring line 231. Subsequently, as illustrated in FIG. 9b, the components 241 are mounted on the side surfaces of the frame portion 240.

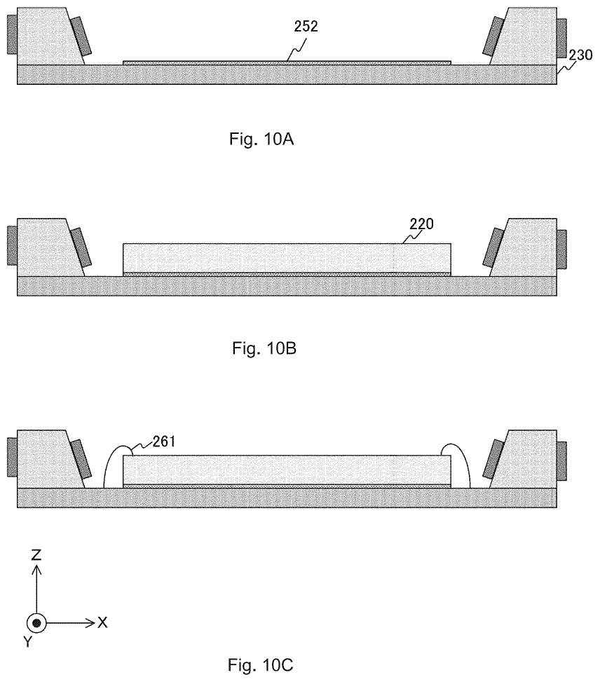

Then, as illustrated in FIG. 10a, on the upper surface of the multilayer wiring substrate 230, the die bond material 252 is applied to a predetermined region surrounded by the frame portion 240, and as illustrated in FIG. 10b, the sensor chip 220 is bonded. Subsequently, as illustrated in FIG. 10c, the sensor chip 220 is connected by the wires 261.

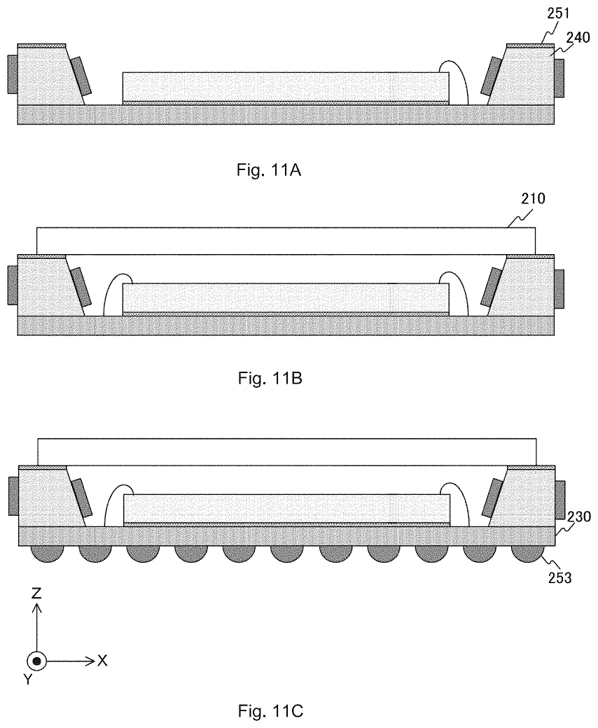

Then, as illustrated in FIG. 11a, the seal material 251 is applied to the upper surface of the frame portion 240, and the seal glass 210 is bonded to the seal material 251 as illustrated in FIG. 11b. Subsequently, as illustrated in FIG. 11c, a predetermined number of solder balls 253 are formed on the lower surface of the multilayer wiring substrate 230, and thus, the semiconductor package 200 is produced.

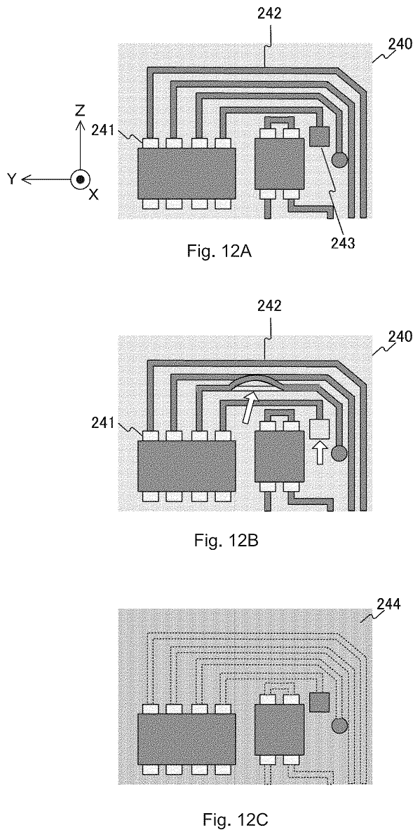

FIG. 12 is examples of plan views of the frame portion 240 before and after application of a solder resist in the first embodiment of the present technology. FIG. 12a is an example of a plan view of the frame portion 240 when viewed from the X-axis direction. As illustrated in FIG. 12a, on the surface of the frame portion 240, a predetermined number of wiring lines 242 are formed, and a predetermined number of components 241 are mounted. A pad 243 is formed as necessary at one end of the wiring line 242.

Here, when a long time elapses without applying anything to the surface of the frame portion 240, as illustrated in FIG. 12b, the wiring line 242 and the pad 243 on the surface might peel off due to oxidation of the circuit. Arrows in FIG. 12b indicate portions where the peeling off has occurred.

Thus, as illustrated in FIG. 12c, protection is preferably provided by applying a solder resist 244 to the surface of the frame portion 240.

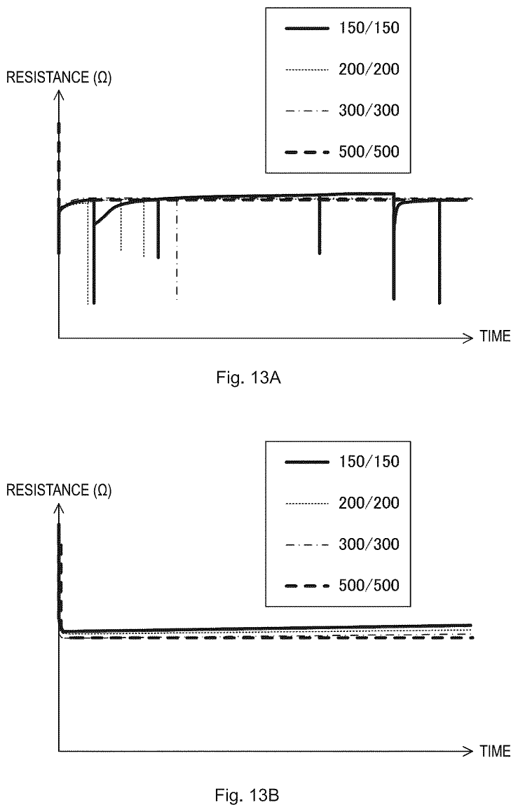

FIG. 13 is graphs showing an example of long-term reliability before and after coating with the solder resist 244 in the first embodiment of the present technology. FIG. 13a shows an example of a change over time in insulation resistance between lines in a case where the solder resist 244 is not applied, and FIG. 13b shows an example of a change over time in insulation resistance between lines in a case where the solder resist 244 is applied.

In FIGS. 13a and 13b, vertical axes represent the insulation resistance between the lines, and horizontal axes represent time. Thick lines indicate characteristics of the insulation resistance between two wiring lines each having a width of 150 micrometers and a space of 150 micrometers between the wiring lines, and thin dotted lines indicate characteristics of the insulation resistance between two wiring lines each having a width of 200 micrometers and a space of 200 micrometers between the wiring lines. Dashed-dotted lines indicate characteristics of the insulation resistance between two wiring lines each having a width of 300 micrometers and a space of 300 micrometers between the wiring lines, and thick dotted lines indicate characteristics of the insulation resistance between two wiring lines each having a width of 500 micrometers and a space of 500 micrometers between the wiring lines.

As shown, as an example, in FIGS. 13a and 13b, by applying the solder resist 244, deterioration of the insulation resistance over time can be suppressed as compared with the case where the solder resist is not applied.

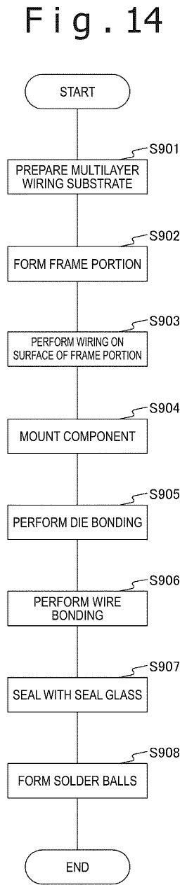

FIG. 14 is a flowchart showing an example of a producing method for the semiconductor package 200 according to the first embodiment of the present technology. First, the multilayer wiring substrate 230 is prepared (step S901), and the frame portion 240 is formed on the upper surface of the multilayer wiring substrate 230 (step S902). Then, the wiring line 242 is formed on the surface of the frame portion 240 (step S903), and the side surface of the frame portion 240 is provided with the components 241 (step S904).

On the upper surface of the multilayer wiring substrate 230, die bonding of the sensor chip 220 is performed (step S905), and wire bonding is performed (step S906). Then, the cavity is sealed with the seal glass 210 (step S907), and a predetermined number of solder balls 253 are formed on the lower surface of the multilayer wiring substrate 230 (step S908). After step S908, various steps are performed as necessary, and producing steps of the semiconductor package 200 are completed.

As described above, according to the first embodiment of the present technology, since the surface of the frame portion 240 is provided with the predetermined number of components 241, the number of components of the mounting substrate 300 can be reduced as compared with a case where the components 241 are mounted on the mounting substrate 300.

### 2. Second Embodiment

In the first embodiment described above, the frame portion 240 is formed around the sensor chip 220 on the upper surface of the multilayer wiring substrate 230, but in this configuration, burrs might occur at the substrate end during dicing. A difference from the first embodiment is that the frame portion 240 covers the upper surface, the lower surface, and the side surfaces of the multilayer wiring substrate 230.

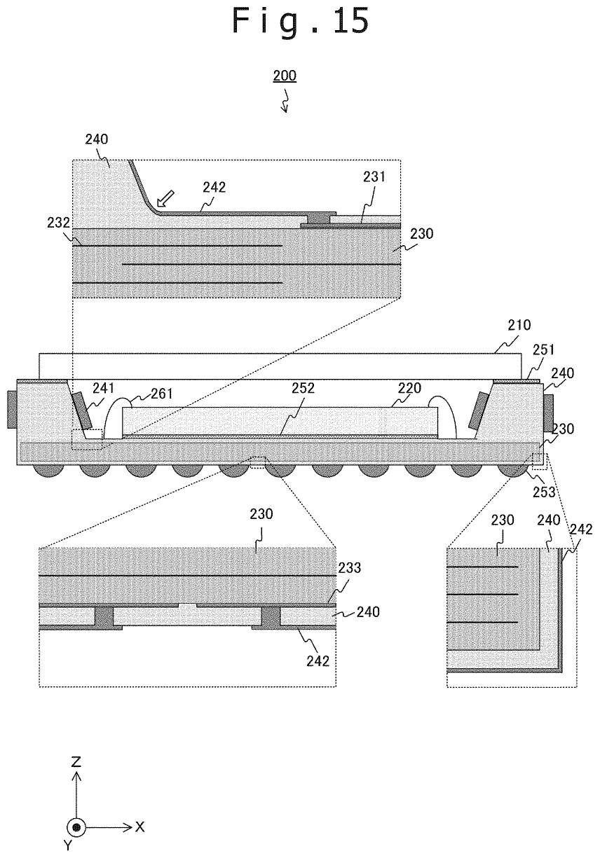

FIG. 15 is a cross-sectional view illustrating a configuration example of the semiconductor package 200 according to the second embodiment of the present technology. The semiconductor package 200 according to the second embodiment is different from the first embodiment in that the frame portion 240 covers the entire upper surface, lower surface, and side surfaces of the multilayer wiring substrate 230. In other words, the frame portion 240 encapsulates the multilayer wiring substrate 230.

The wiring line 231 is formed on the upper surface of the multilayer wiring substrate 230, and the upper surface of the wiring line 231 is covered with a resin of the frame portion 240. The wiring line 242 is formed on the upper surface of the frame portion 240, and is electrically connected to the wiring line 231 via a hole formed on the lower surface.

The side surfaces of the multilayer wiring substrate 230 are covered with the resin of the frame portion 240, and the wiring line 242 is formed on the surface of the resin. The components 241 can be mounted also on the side surfaces of the multilayer wiring substrate 230.

In addition, a wiring line 233 is formed on the lower surface of the multilayer wiring substrate 230, and the lower surface of the wiring line 233 is covered with the resin of the frame portion 240. The wiring line 242 is formed on the lower surface of the frame portion 240, and is electrically connected to the wiring line 233 via a hole formed on the lower surface.

As illustrated in FIG. 15, the frame portion 240 covers (encapsulates) the upper surface, the lower surface, and the side surfaces of the multilayer wiring substrate 230, and thus burrs do not occur at the substrate end of the multilayer wiring substrate 230. In addition, the frame portion 240 blocks electromagnetic waves from the outside, and thus a shielding effect is obtained. Further, since the resin of the frame portion 240 is less likely to absorb moisture than the multilayer wiring substrate 230, a structure less likely to absorb moisture can be obtained, and reliability can be improved.

Further, since the frame portion 240 as the MID covers the lower surface of the multilayer wiring substrate 230, when the lower surface is a ball grid array (BGA), the wiring lines can be easily routed, and the wiring can be performed even when the number of pins of the BGA is large.

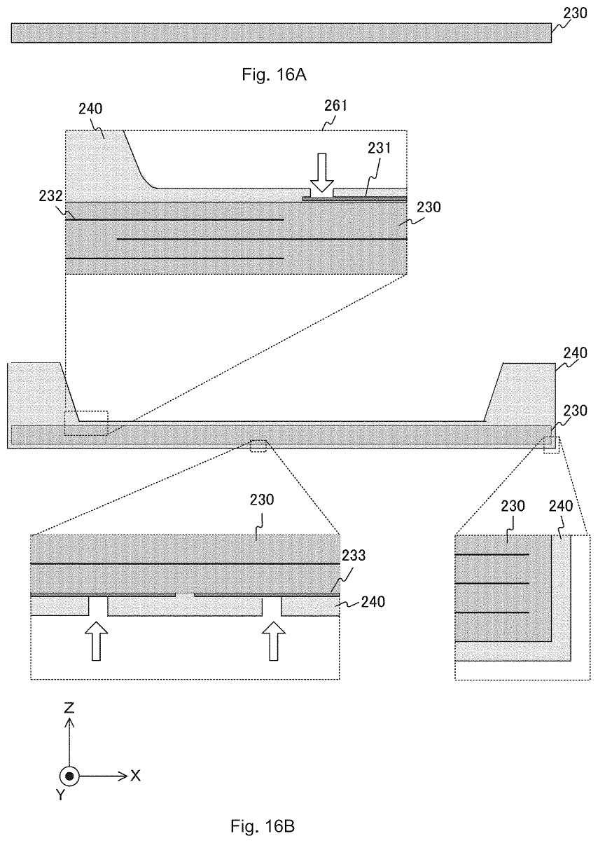

Next, a producing method for the semiconductor package 200 will be described with reference to FIGS. 16 to 19. First, as illustrated in FIG. 16 a, the multilayer wiring substrate 230 is prepared. Subsequently, as illustrated in FIG. 16b, the frame portion 240 covering the upper surface, the lower surface, and the side surfaces of the multilayer wiring substrate 230 is molded. Then, holes reaching the wiring lines 231 and 233 on the substrate side are opened on the upper surface and the lower surface, respectively, of the frame portion 240 by a laser or the like. Arrows in FIG. 16b indicate portions that are opened.

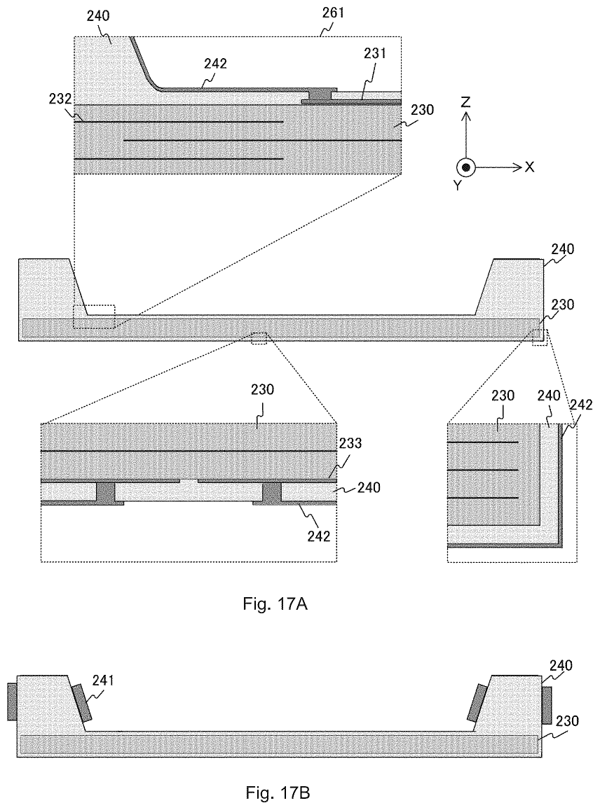

Then, as illustrated in FIG. 17a, the wiring line 242 is formed on the surface of the frame portion 240. On the upper and lower surfaces of the frame portion 240, the wiring line 242 is connected to the wiring lines 231 and 233 on the substrate side via the holes. Subsequently, as illustrated in FIG. 17b, the components 241 are mounted on the side surfaces of the frame portion 240.

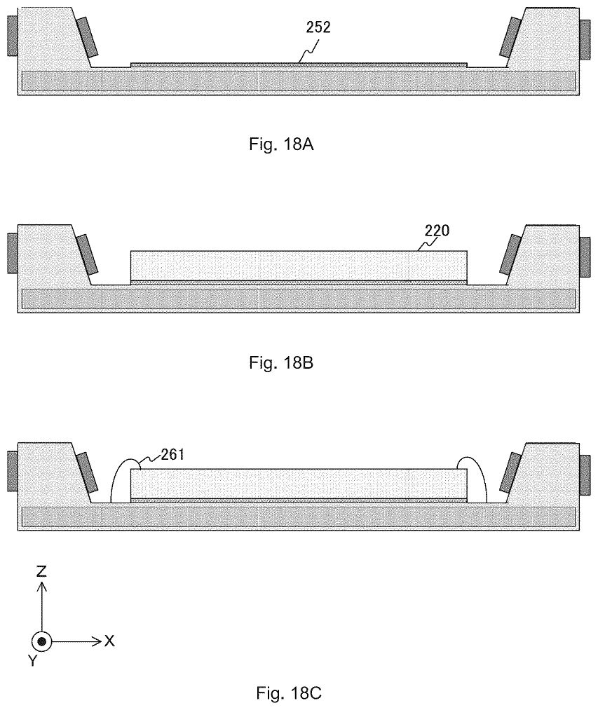

Then, as illustrated in FIG. 18a, on the upper surface of the multilayer wiring substrate 230, the die bond material 252 is applied to a predetermined region surrounded by the frame portion 240, and as illustrated in FIG. 18b, the sensor chip 220 is bonded. Subsequently, as illustrated in FIG. 18c, the sensor chip 220 is connected by the wires 261.

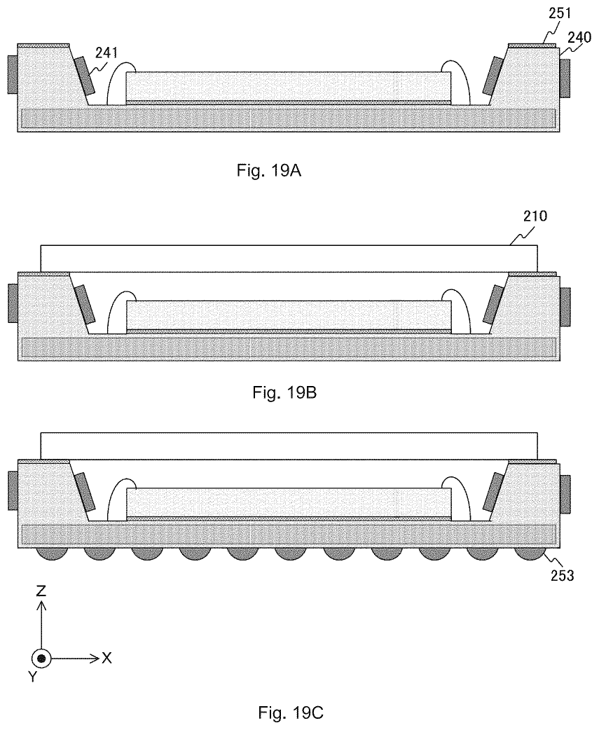

Then, as illustrated in FIG. 19a, the seal material 251 is applied to the upper surface of the frame portion 240, and the seal glass 210 is bonded to the seal material 251 as illustrated in FIG. 19b. Subsequently, as illustrated in FIG. 19c, a predetermined number of solder balls 253 are formed on the lower surface of the frame portion 240, and the semiconductor package 200 is produced.

As described above, according to the second embodiment of the present technology, the frame portion 240 covers the upper surface, the lower surface, and the side surfaces of the multilayer wiring substrate 230, and thus the occurrence of burrs at the substrate end can be suppressed. Further, a shielding effect and high reliability can be achieved.

### Modification

In the second embodiment described above, the upper surface, the lower surface, and the side surfaces of the multilayer wiring substrate 230 are covered with the frame portion 240, but a configuration may be employed in which the lower surface is not covered. The semiconductor package 200 according to a modification of the second embodiment is different from that according to the second embodiment in that the frame portion 240 covers the upper surface and the side surfaces of the multilayer wiring substrate 230 but does not cover the lower surface thereof.

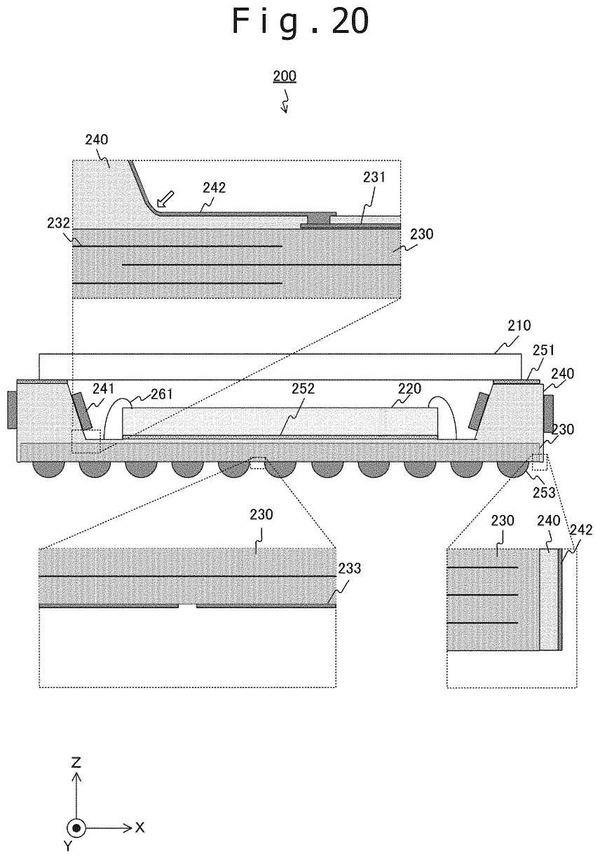

FIG. 20 is a cross-sectional view illustrating a configuration example of the semiconductor package 200 according to the modification of the second embodiment of the present technology. The semiconductor package 200 according to the modification of the second embodiment is different from that according to the second embodiment in that the frame portion 240 covers the upper surface and the side surfaces of the multilayer wiring substrate 230 but does not cover the lower surface thereof.

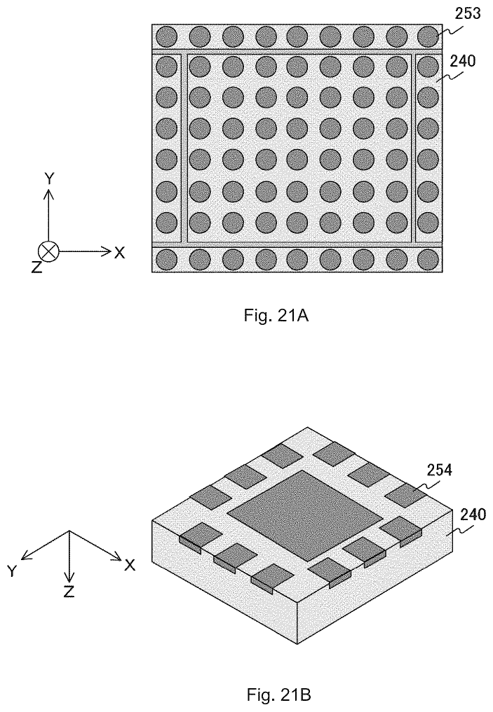

FIG. 21 is examples of a bottom view and a perspective view illustrating the semiconductor package 200 according to the modification of the second embodiment of the present technology. FIG. 21a is the example of the bottom view of the semiconductor package 200. As illustrated in FIG. 21a, a BGA in which a predetermined number of solder balls 253 are arrayed in a two-dimensional lattice pattern is formed on the lower surface.

In the modification of the second embodiment in which the lower surface of the multilayer wiring substrate 230 is not covered, instead of the solder balls 253, a predetermined number of pads 254 may be disposed on the lower surface, as illustrated in FIG. 21b. Such a semiconductor package 200 is called a quad flat non-leaded package (QFN).

In addition, when the frame portion 240 does not cover the lower surface of the multilayer wiring substrate 230 at all, it is difficult to connect the wiring line 242 on the surface of the multilayer wiring substrate 230 to the solder balls 253. Thus, a part of the lower surface may be covered with the resin of the frame portion 240. In this case, a step might be generated in the solder ball 253 between a portion with the resin and a portion without the resin. However, in the resin on the lower surface, by forming a hole at a portion of a land where the solder ball 253 is to be formed by a laser or by performing exposure molding such that the portion of the land is exposed, the step can be eliminated.

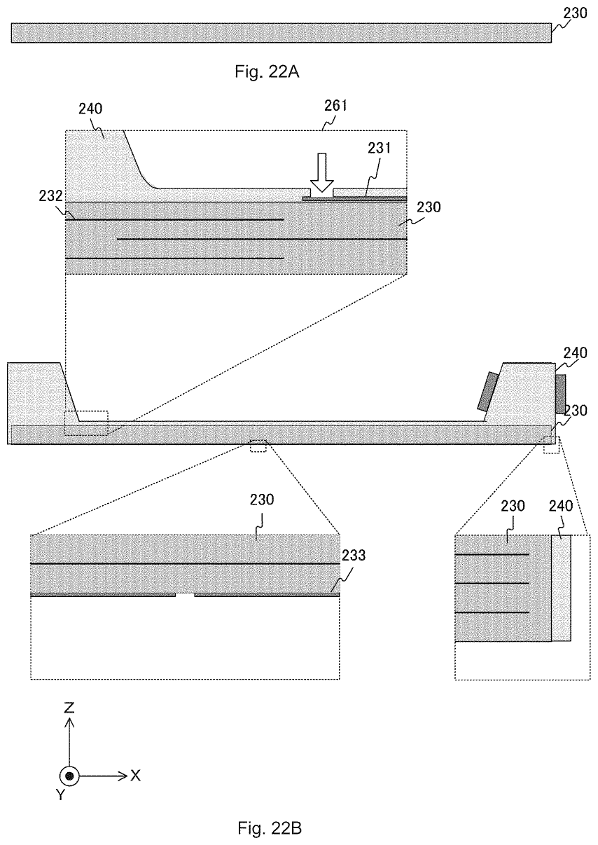

Next, a producing method for the semiconductor package 200 will be described with reference to FIGS. 22 to 25. First, as illustrated in FIG. 22a, the multilayer wiring substrate 230 is prepared. Subsequently, as illustrated in FIG. 22b, the frame portion 240 covering the upper surface and the side surfaces of the multilayer wiring substrate 230 is molded. Then, on the upper surface of the frame portion 240, a hole reaching the wiring line 231 on the substrate side is opened by a laser or the like. An arrow in FIG. 22b indicates a portion that is opened.

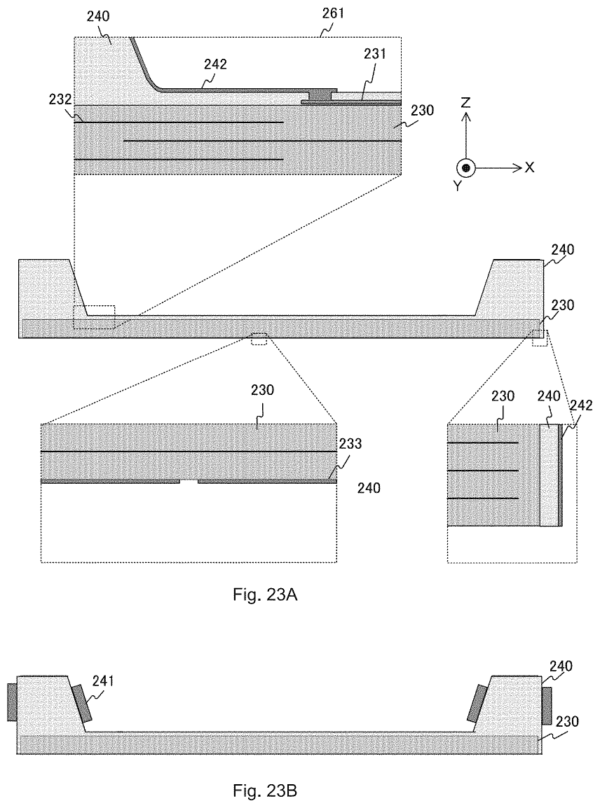

Then, as illustrated in FIG. 23a, the wiring line 242 is formed on the surface of the frame portion 240. On the upper surface of the frame portion 240, the wiring line 242 is connected to the wiring lines 231 and 233 on the substrate side via the holes. Subsequently, as illustrated in FIG. 23b, the components 241 are mounted on the side surfaces of the frame portion 240.

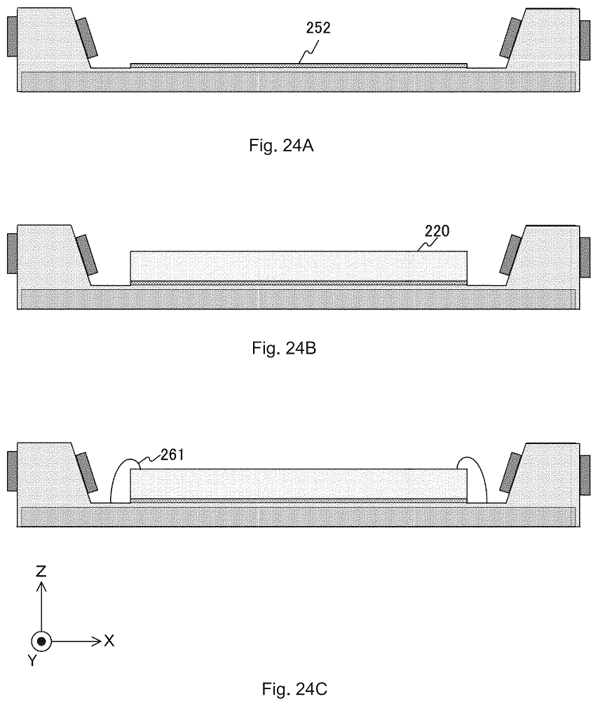

Then, as illustrated in FIG. 24a, on the upper surface of the multilayer wiring substrate 230, the die bond material 252 is applied to a predetermined region surrounded by the frame portion 240, and as illustrated in FIG. 24b, the sensor chip 220 is bonded. Subsequently, as illustrated in FIG. 24c, the sensor chip 220 is connected by the wires 261.

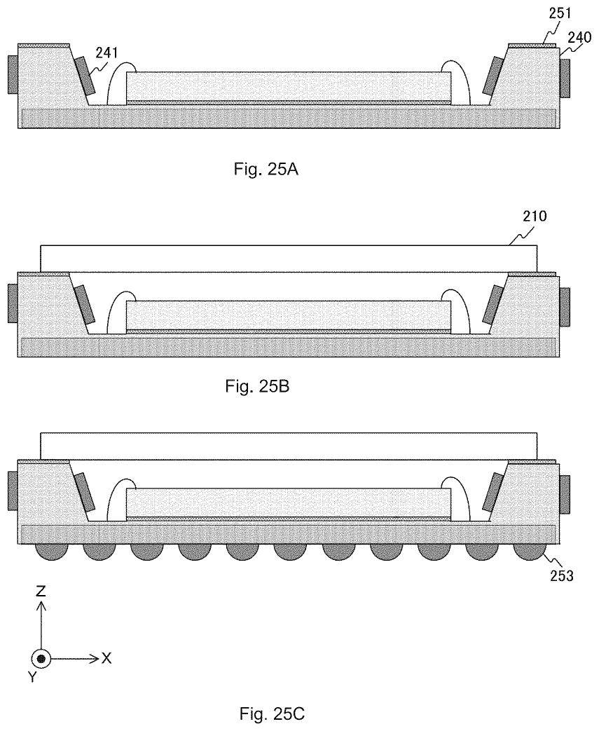

Then, as illustrated in FIG. 25a, the seal material 251 is applied to the upper surface of the frame portion 240, and the seal glass 210 is bonded to the seal material 251 as illustrated in FIG. 25b. Subsequently, as illustrated in FIG. 25c, a predetermined number of solder balls 253 are formed on the lower surface of the multilayer wiring substrate 230, and the semiconductor package 200 is produced.

As described above, according to the modification of the second embodiment of the present technology, since the frame portion 240 does not cover the lower surface of the multilayer wiring substrate 230, QFN can be obtained in addition to a BGA package.

### 3. Third Embodiment

In the second embodiment described above, the cavity is sealed by the seal glass 210, but flare might occur due to light reflected by the wiring line 242 on the frame portion 240 and the wires 261. The semiconductor package 200 according to the third embodiment is different from that according to the second embodiment in that flare is suppressed by shielding a part of the seal glass 210 from light.

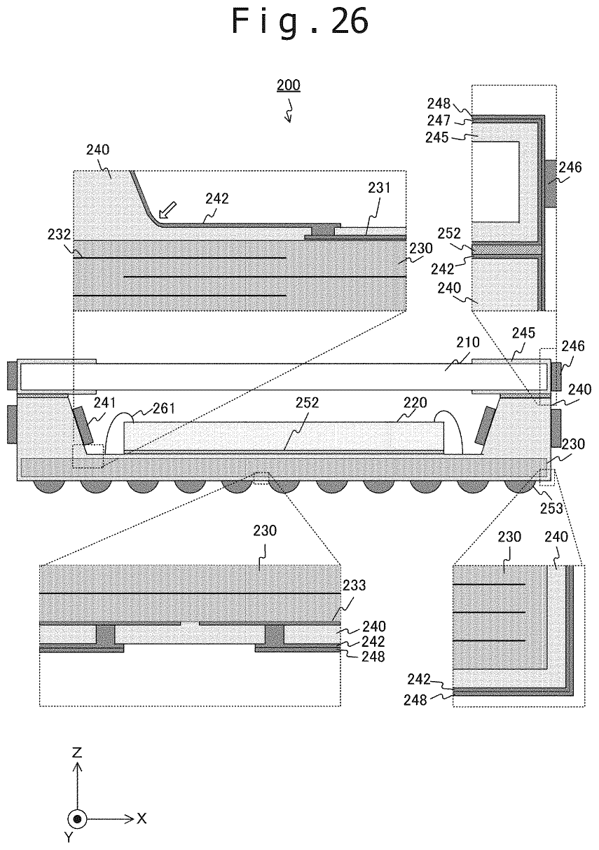

FIG. 26 is a cross-sectional view illustrating a configuration example of a semiconductor package 200 according to the third embodiment of the present technology. The semiconductor package 200 according to the third embodiment is different from that according to the second embodiment in that a light-shielding film 245 that shields a part of the seal glass 210 from light is further provided.

The light-shielding film 245 is a resin that covers side surfaces and the vicinity of an outer periphery of each of an upper surface and a lower surface of the seal glass 210, and for example, an MID is used. A wiring line 247 is formed on a surface of the light-shielding film 245. A predetermined number of components 246 can be mounted on side surfaces of the light-shielding film 245. As these components 246, passive components such as a capacitor and a resistor, and active components such as a transistor and a diode are assumed. Further, a wiring line 248 is formed on the outer side of the wiring line 247 on the seal glass 210 side and the wiring line 242 on the frame portion 240 side, and the wiring line 247 and the wiring line 242 are electrically connected to each other through the wiring line 248. The component 246 is an example of the second component described in the appended claims.

As illustrated in FIG. 26, by forming the light-shielding film 245, the flare can be prevented. Further, by using the MID as the light-shielding film 245, the side surfaces of the seal glass 210 may be provided with the components 246.

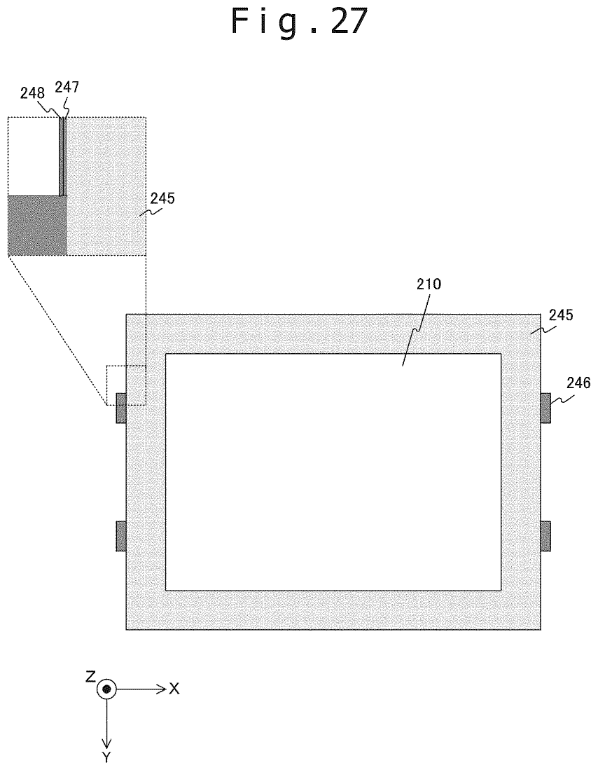

FIG. 27 is an example of a top view of the semiconductor package 200 according to the third embodiment of the present technology. As illustrated in FIG. 27, the light-shielding film 245 is formed along an outer periphery of the seal glass 210, and the upper surface of the light-shielding film 245 has a frame shape when viewed from the Z-axis direction. The wiring lines 247 and 248 are formed on the surface of the light-shielding film 245, and the components 246 can be mounted.

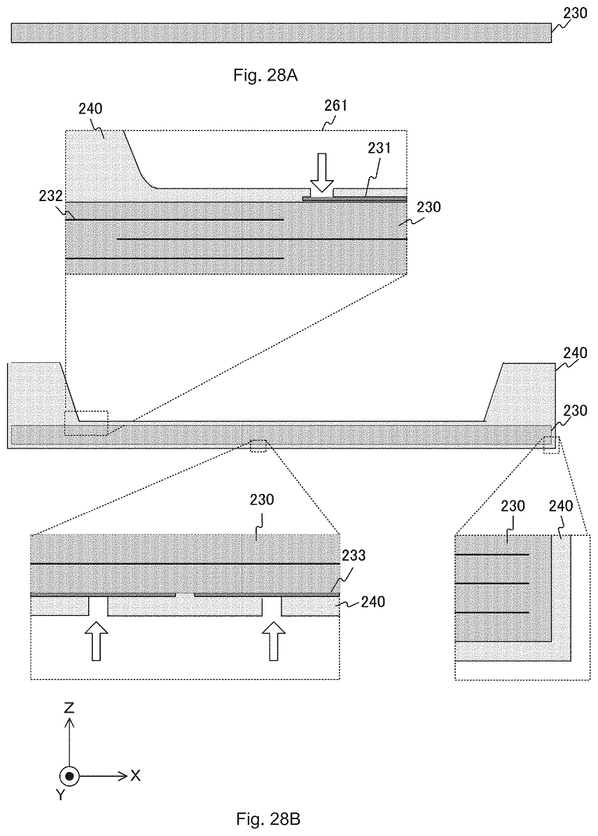

Next, a producing method for the semiconductor package 200 will be described with reference to FIGS. 28 to 31. First, as illustrated in FIG. 28 a, the multilayer wiring substrate 230 is prepared. Subsequently, as illustrated in FIG. 28b, the frame portion 240 covering the upper surface, the lower surface, and the side surfaces of the multilayer wiring substrate 230 is molded. Then, holes reaching the wiring lines 231 and 233 on the substrate side are opened on the upper surface and the lower surface, respectively, of the frame portion 240 by a laser or the like. Arrows in FIG. 28b indicate portions that are opened.

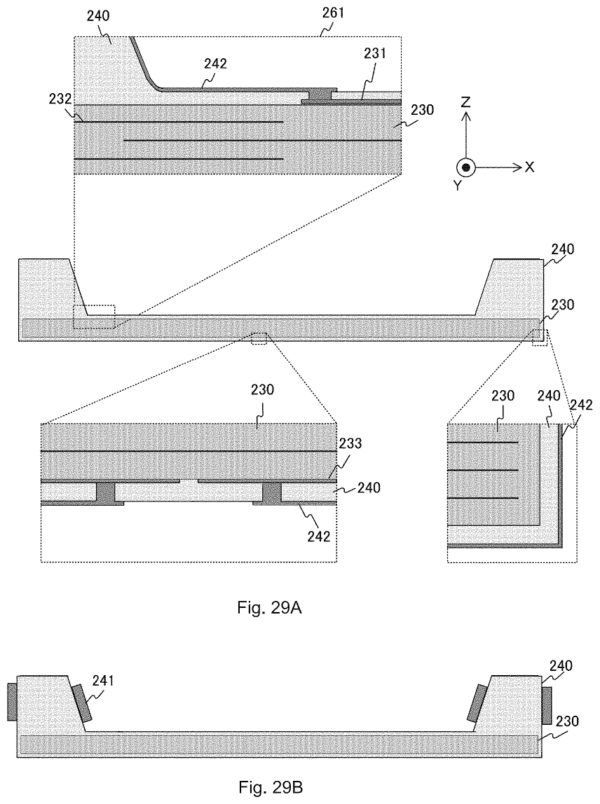

Then, as illustrated in FIG. 29a, the wiring line 242 is formed on the surface of the frame portion 240. On the upper surface of the frame portion 240, the wiring line 242 is connected to the wiring lines 231 and 233 on the substrate side via the holes. Subsequently, as illustrated in FIG. 29b, the components 241 are mounted on the side surfaces of the frame portion 240.

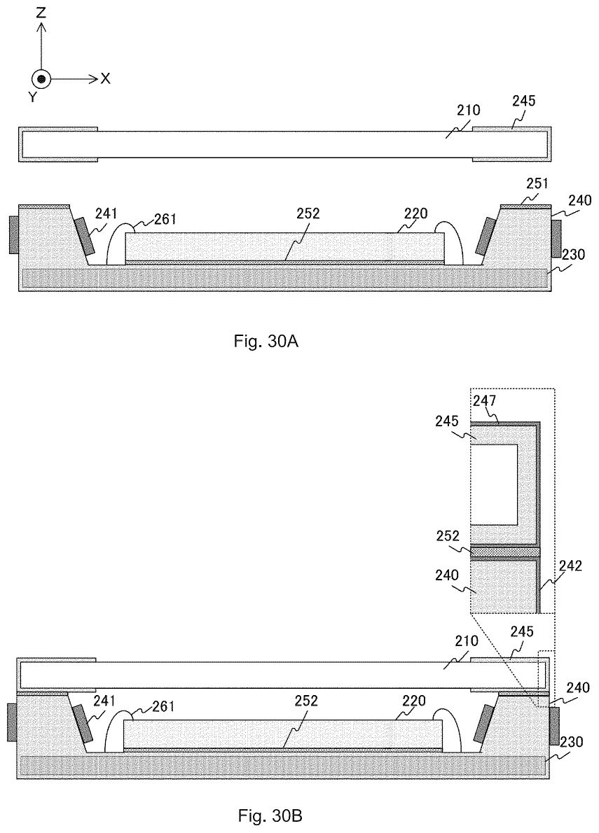

Then, as illustrated in FIG. 30a, the light-shielding film 245 is formed on the seal glass 210, and the seal material 251 is applied to the upper surface of the frame portion 240. Subsequently, as illustrated in FIG. 30b, the seal glass 210 on which the light-shielding film 245 is formed is bonded to the upper surface of the frame portion 240.

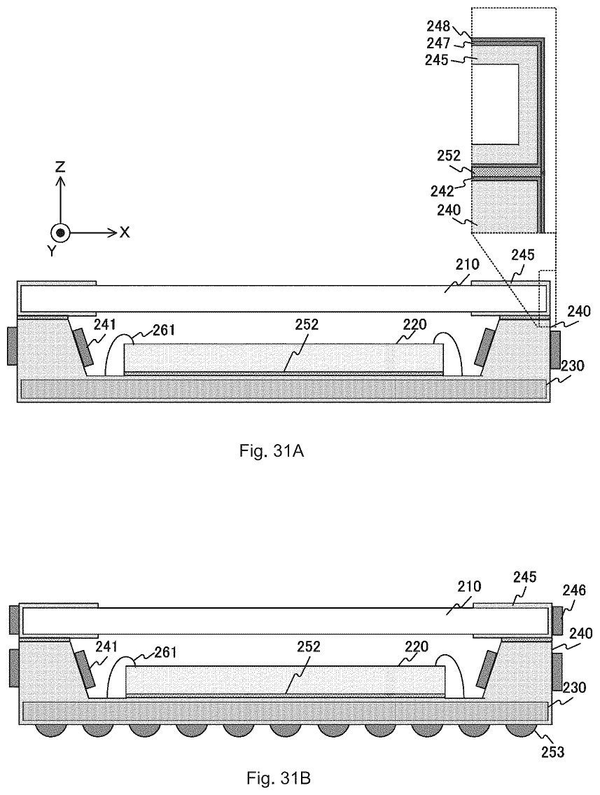

Then, as illustrated in FIG. 31a, the wiring line 248 is formed, and the wiring line 247 on the upper side and the wiring line 242 on the lower side are electrically connected to each other through the wiring line 248. Subsequently, as illustrated in FIG. 31 b, the components 246 are mounted, and a predetermined number of solder balls 253 are formed on the lower surface of the frame portion 240.

The modification of the second embodiment, in which the lower surface of the multilayer wiring substrate 230 is not covered, can be applied to the third embodiment. The light-shielding film 245 of the third embodiment may be formed on the semiconductor package 200 of the first embodiment.

As described above, according to the third embodiment of the present technology, since the light-shielding film 245 is formed on the seal glass 210, the flare can be prevented. Further, by using the MID as the light-shielding film 245, the components 246 can be mounted also on the side surfaces of the seal glass 210.

### Modification

In the third embodiment described above, the wiring lines 242 are formed also on the side surfaces on the inner side of the frame portion 240, but in this configuration, it is difficult to simplify the producing steps. The semiconductor package 200 according to the third embodiment is different from the third embodiment in that wiring is not performed on the side surfaces on the inner side of the frame portion 240.

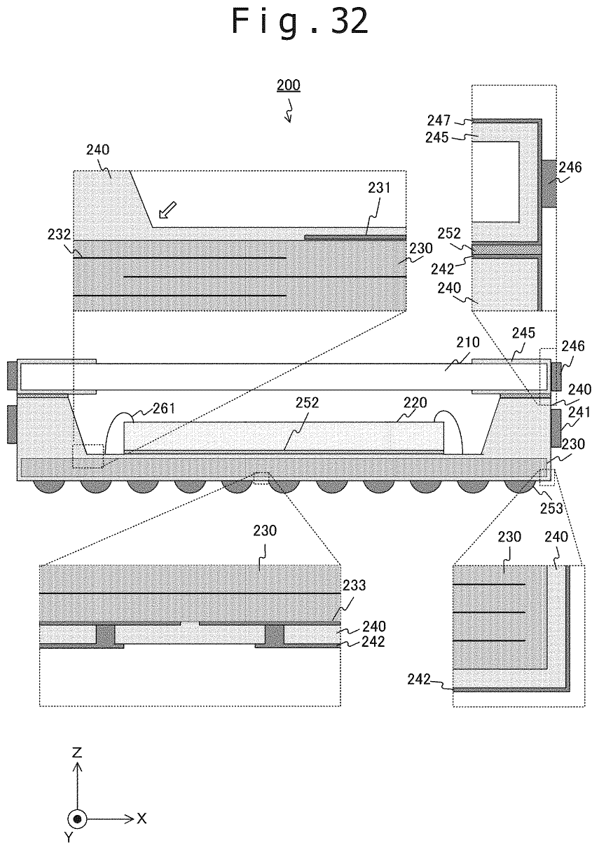

FIG. 32 is a cross-sectional view illustrating a configuration example of the semiconductor package 200 according to a modification of the third embodiment of the present technology. The semiconductor package 200 according to the modification of the third embodiment is different from that according to the third embodiment in that the wiring lines 242 are not formed on the side surfaces on the inner side of the frame portion 240. Further, it is assumed that the components 241 are not mounted on the side surfaces on the inner side of the frame portion 240.

By not performing wiring on the inner side, in other words, on the cavity side, of the frame portion 240, the wiring line 247 on the upper side and the wiring line 242 on the lower side can be connected to each other when the seal glass 210 is mounted. As a result, a step of forming the wiring line 248 to connect the wiring line 247 and the wiring line 242 to each other is not necessary. In addition, the contour of the cross-sectional shape of the frame portion 240 near the boundary between the frame portion 240 and the multilayer wiring substrate 230 does not need to have an arc shape.

The modification of the second embodiment, in which the lower surface of the multilayer wiring substrate 230 is not covered, can be applied to the modification of the third embodiment.

As described above, according to the modification of the third embodiment of the present technology, since wiring is not performed on the cavity side, the producing steps can be simplified.

### 4. Fourth Embodiment

In the third embodiment described above, the frame portion 240 is formed for each semiconductor package 200, but when a plurality of the semiconductor packages 200 are produced, it is more efficient to cut a collective substrate in which the plurality of semiconductor packages are integrated. A producing method of a fourth embodiment is different from that according to the third embodiment in that the collective substrate is produced and cut.

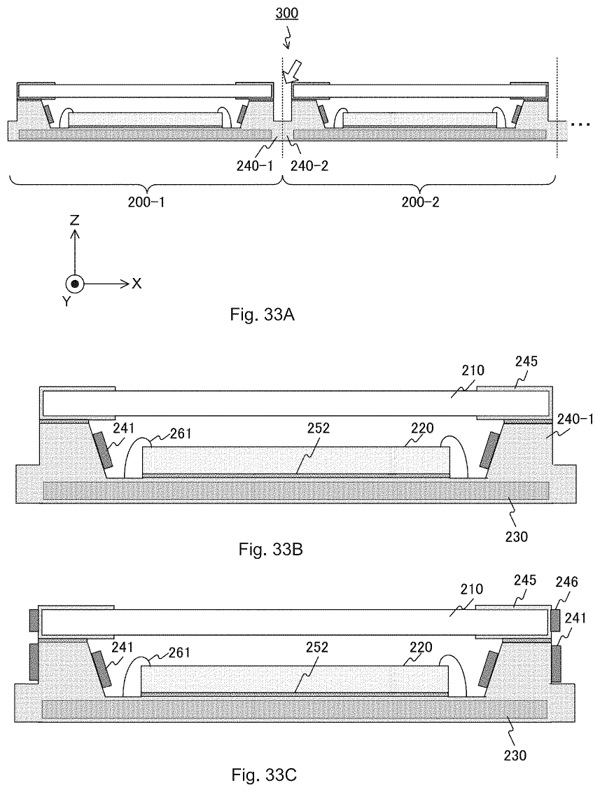

FIG. 33 is views for explaining the producing method according to the fourth embodiment of the present technology. As illustrated in FIG. 33a, a collective substrate in which the plurality of semiconductor packages such as semiconductor packages 200-1 and 200-2 are integrated is produced. The plurality of frame portions 240 (the frame portions 240-1, 240-2, and the like) in the collective substrate are connected to each other at the side surfaces thereof and are integrated with each other. In addition, a recessed portion is formed in a connection portion thereof so as to be easily cut. An arrow in FIG. 33a indicates the recessed portion.

Further, wire bonding is performed for each semiconductor package 200, and the seal glass 210 is bonded to the semiconductor package 200.

Subsequently, as illustrated in FIG. 33b, the collective substrate is cut at the recessed portion, and the plurality of semiconductor packages 200 are cut out. As illustrated in FIG. 33c, the components 246 and 241 are mounted on the side surfaces of the seal glass 210 and the side surfaces of the frame portion 240, respectively, for each semiconductor package 200. Then, various steps such as formation of the solder balls 253 (not illustrated) are performed.

As described above, by producing, at one time, the collective substrate including the plurality of frame portions 240, producing efficiency is improved and producing cost can be reduced as compared with a case where the frame portions 240 are individually molded.

The modification of the second embodiment in which the lower surface of the multilayer wiring substrate 230 is not covered can be applied to the fourth embodiment. The producing method of the fourth embodiment can be applied to the first embodiment and the second embodiment.

As described above, according to the fourth embodiment of the present technology, the collective substrate is produced and cut, and thus the producing cost can be reduced as compared with the third embodiment in which the frame portion 240 is individually molded.

### 5. Fifth Embodiment

In the first embodiment described above, the wiring line 242 on the frame portion 240 side and the wiring line 231 on the substrate side are connected to each other by plating processing, but the connection method is not limited thereto. A producing method for the semiconductor package 200 according to the fifth embodiment is different from that according to the first embodiment in that the multilayer wiring substrate 230 and the frame portion 240 are connected to each other using solder.

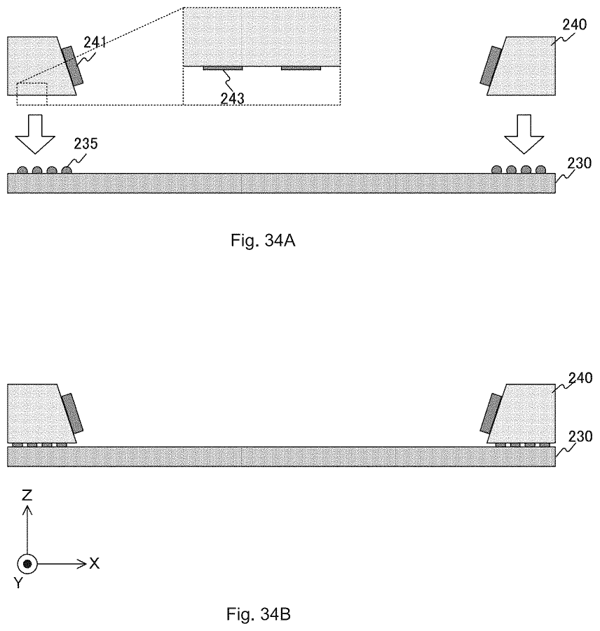

FIG. 34 is views for explaining the producing method according to the fifth embodiment of the present technology. As illustrated in FIG. 34a, a predetermined number of solder balls 235 are formed at positions to which the frame portion 240 is connected on the upper surface of the multilayer wiring substrate 230. The solder balls 235 are connected to wiring lines (not illustrated) on the substrate side. The frame portion 240 is molded in a state where a predetermined number of pads 243 are formed on the lower surface of the frame portion 240. The pad 243 is connected to the wiring line 242 (not illustrated) formed on the surface of the frame portion 240.

Subsequently, as illustrated in FIG. 34b, part of the solder balls 235 is melted and connected to the pad 243. Then, various steps such as wire bonding and bonding of the seal glass 210 are performed.

The fifth embodiment can be applied to each of the second, third, and fourth embodiments.

As described above, according to the fifth embodiment of the present technology, the multilayer wiring substrate 230 and the frame portion 240 are connected to each other using solder, and thus electrical connection with the frame portion 240 can be easily performed.

### 6. Sixth Embodiment

In the first embodiment described above, the wiring line 242 on the frame portion 240 side and the wiring line 231 on the substrate side are connected to each other by plating processing, but the connection method is not limited thereto. A producing method for the semiconductor package 200 according to the sixth embodiment is different from that according to the first embodiment in that an electrode on the upper surface of the multilayer wiring substrate 230 and an electrode on the lower surface of the frame portion 240 are connected to each other by thermocompression bonding.

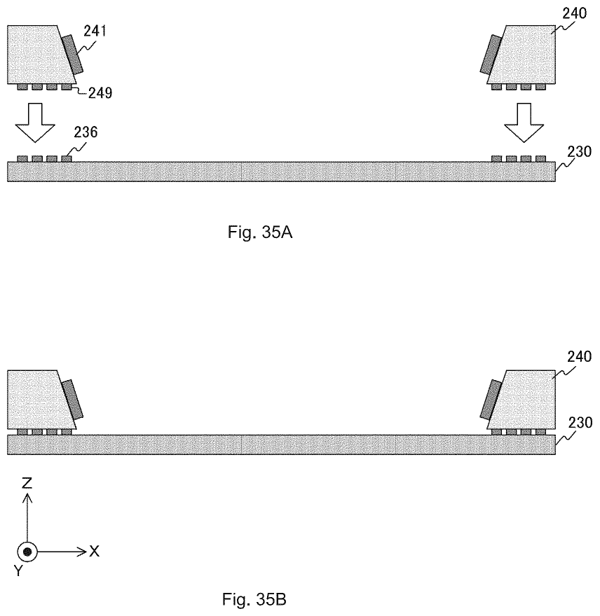

FIG. 35 is views for explaining the producing method according to the sixth embodiment of the present technology. As illustrated in FIG. 35a, a predetermined number of electrodes 236 are formed at positions to which the frame portion 240 is connected on the upper surface of the multilayer wiring substrate 230. The electrode 236 is connected to a wiring line (not illustrated) on the substrate side. The frame portion 240 is molded in a state where a predetermined number of electrodes 249 are formed on the lower surface of the frame portion 240. The electrode 249 is connected to the wiring line 242 (not illustrated) formed on the surface of the frame portion 240.

Subsequently, as illustrated in FIG. 35b, the electrode 236 and the electrode 249 are connected to each other by the thermocompression bonding. In this thermocompression bonding, an anisotropic conductive paste (ACP) or an anisotropic conductive film (ACF) is used. Electrical connection between the multilayer wiring substrate 230 and the frame portion 240 can be easily performed by the thermocompression bonding.

The sixth embodiment can be applied to each of the second, third, and fourth embodiments.

As described above, according to the sixth embodiment of the present technology, the multilayer wiring substrate 230 and the frame portion 240 are connected to each other by the thermocompression bonding, and thus, the electrical connection therebetween can be easily performed.

### 7. Seventh Embodiment

In the first embodiment described above, the sensor chip 220 is mounted in the cavity on the inner side of the frame portion 240, but a semiconductor chip can also be mounted on the outer side of the frame portion 240. The semiconductor package 200 according to the seventh embodiment is different from that according to the first embodiment in that a semiconductor chip is also mounted on the outer side of the frame portion 240.

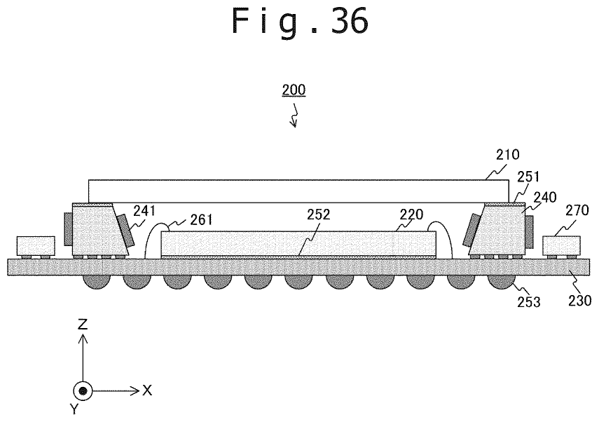

FIG. 36 is a cross-sectional view illustrating a configuration example of the semiconductor package 200 according to the seventh embodiment of the present technology. The semiconductor package 200 according to the seventh embodiment is different from that according to the first embodiment in that the semiconductor package 200 further includes a predetermined number of semiconductor chips 270.

The area of the multilayer wiring substrate 230 in the seventh embodiment is larger than the area of a portion surrounded by an outer periphery of the frame portion 240. Thus, some space is generated on the outer side of the frame portion 240 when viewed from above. The semiconductor chips 270 are disposed on the outer side of the frame portion on the upper surface of the multilayer wiring substrate 230. The addition of the semiconductor chips 270 can further improve the performance of the semiconductor package 200. The semiconductor chip 270 is an example of the second semiconductor chip described in the appended claims.

The seventh embodiment can be applied to each of the second, third, fourth, fifth, and sixth embodiments.

As described above, according to the seventh embodiment of the present technology, since the semiconductor chips 270 are also disposed on the outer side of the frame portion 240, the performance of the semiconductor package 200 can be further improved.

### 8. Eighth Embodiment

In the first embodiment described above, the frame portion 240 is formed on the multilayer wiring substrate 230, but the frame portion 240 and the substrate may be integrally molded. The semiconductor package according to the eighth embodiment is different from that according to the first embodiment in that the frame portion 240 and the substrate are integrally molded.

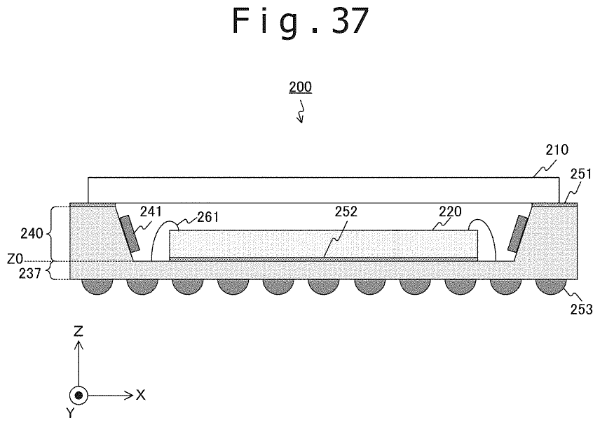

FIG. 37 is a cross-sectional view illustrating a configuration example of the semiconductor package 200 according to the eighth embodiment of the present technology. The semiconductor package 200 according to the eighth embodiment is different from that according to the first embodiment in that an MID is formed in a plate shape with the frame portion. In the MID, a portion having a plate shape below a coordinate ZO is defined as a wiring substrate 237, and a portion having a frame shape above the wiring substrate 237 is defined as the frame portion 240. The wiring substrate 237 is an example of the semiconductor substrate described in the appended claims.

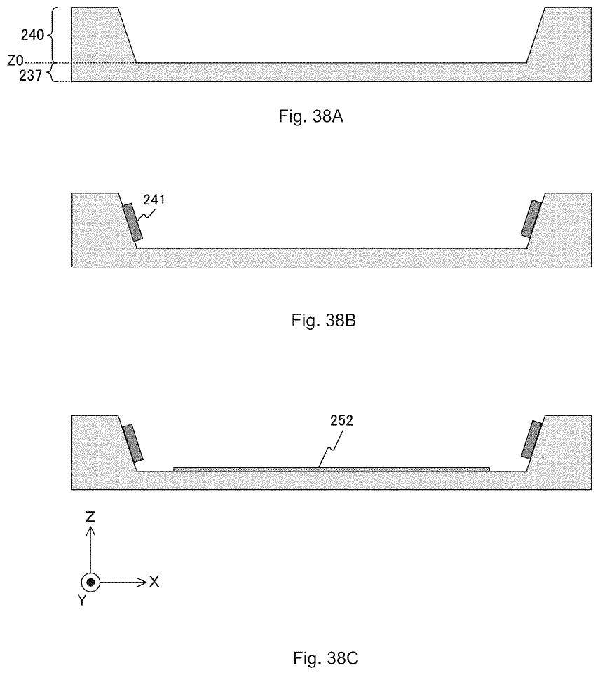

Next, a producing method for the semiconductor package 200 will be described with reference to FIGS. 38 to 40. As illustrated in FIG. 38a, the wiring substrate 237 (that is, MID) on which the frame portion 240 is formed is integrally molded. Subsequently, as illustrated in FIG. 38b, the components 241 are disposed. Subsequently, as illustrated in FIG. 38c, the die bond material 252 is applied to the upper surface of the wiring substrate 237.

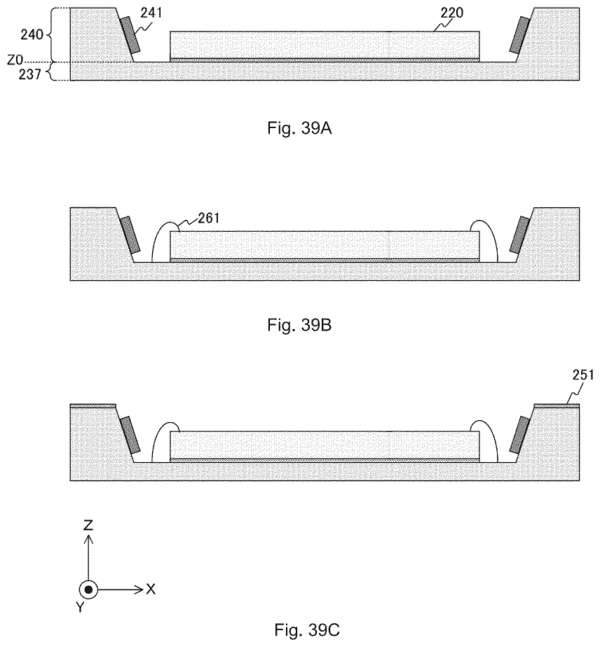

Then, as illustrated in FIG. 39a, the sensor chip 220 is bonded. Subsequently, as illustrated in FIG. 39b, the sensor chip 220 is connected by the wires 261. Subsequently, as illustrated in FIG. 39c, the seal material 251 is applied to the upper surface of the frame portion 240.

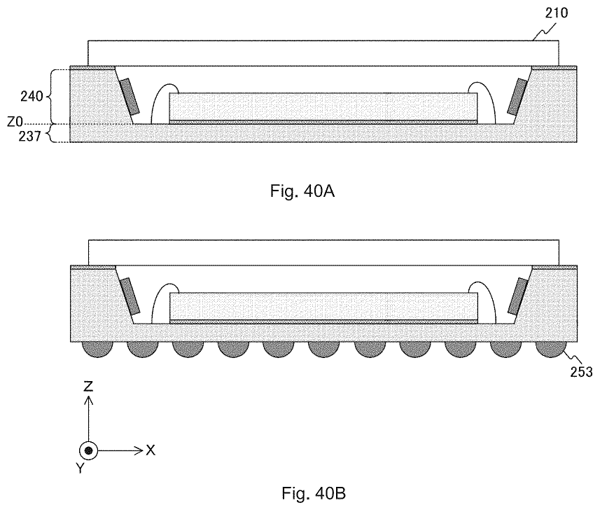

Then, as illustrated in FIG. 40a, the seal glass 210 is bonded. Subsequently, as illustrated in FIG. 40b, a predetermined number of solder balls 253 are formed on the lower surface of the wiring substrate 237, and the semiconductor package 200 is produced.

The eighth embodiment can be applied to each of the third, fourth, and seventh embodiments.

As described above, according to the eighth embodiment of the present technology, the frame portion 240 and the wiring substrate 237 are integrally molded, and thus a step of connecting the frame portion 240 and the substrate to each other is not necessary.

### 9. Ninth Embodiment

In the eighth embodiment described above, the components 241 are disposed on the side surfaces on the inner side of the frame portion 240, but in this configuration, when the size of the components 241 is large, the components 241 may interfere with the wires 261 or the sensor chip 220. The semiconductor package 200 according to the ninth embodiment is different from that according to the eighth embodiment in that the components 241 are disposed in recessed portions formed on the side surfaces of the frame portion 240.

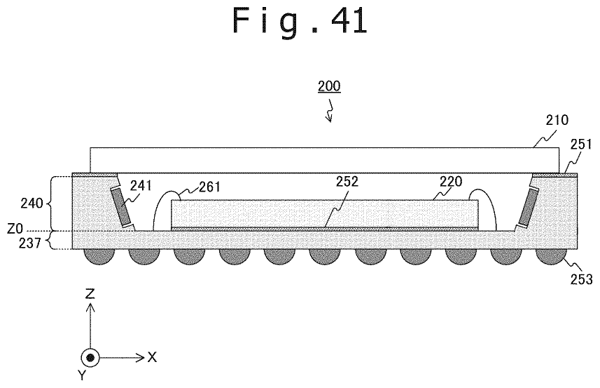

FIG. 41 is a cross-sectional view illustrating a configuration example of the semiconductor package 200 according to the ninth embodiment of the present technology. The semiconductor package 200 according to the ninth embodiment is different from that according to the eighth embodiment in that the recessed portions are formed on the side surfaces on the inner side of the frame portion 240 and the components 241 are disposed in the recessed portions. Note that recessed portions may be formed on the side surfaces on the outer side of the frame portion 240, and the components 241 may be disposed in the recessed portions.

As described above, by disposing the components 241 in the recessed portions on the side surfaces of the frame portion 240, interference between the component 241 and the wire 261 or the like can be avoided.

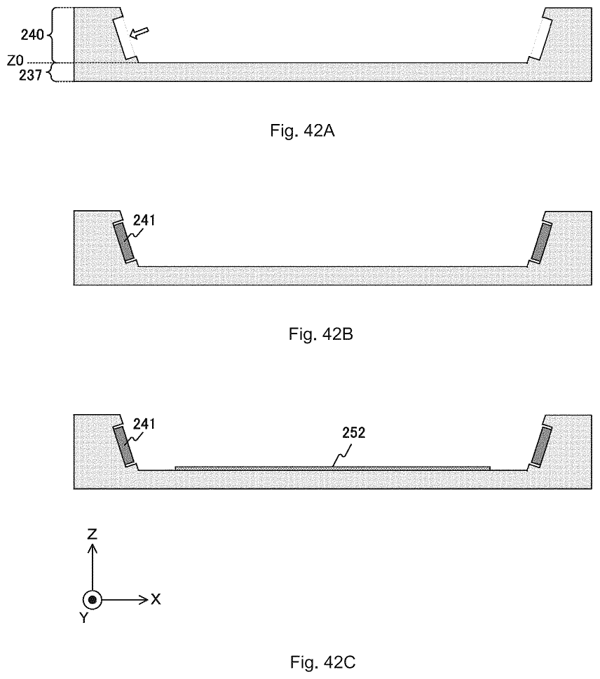

Next, a producing method for the semiconductor package 200 will be described with reference to FIGS. 42 to 44. As illustrated in FIG. 42a, the frame portion 240 with the recessed portions formed on the side surfaces and the wiring substrate 237 (MID) are integrally molded. An arrow in FIG. 42a indicates the recessed portion. Subsequently, as illustrated in FIG. 42b, the components 241 are disposed in the recessed portions. Subsequently, as illustrated in FIG. 42c, the die bond material 252 is applied to the upper surface of the wiring substrate 237.

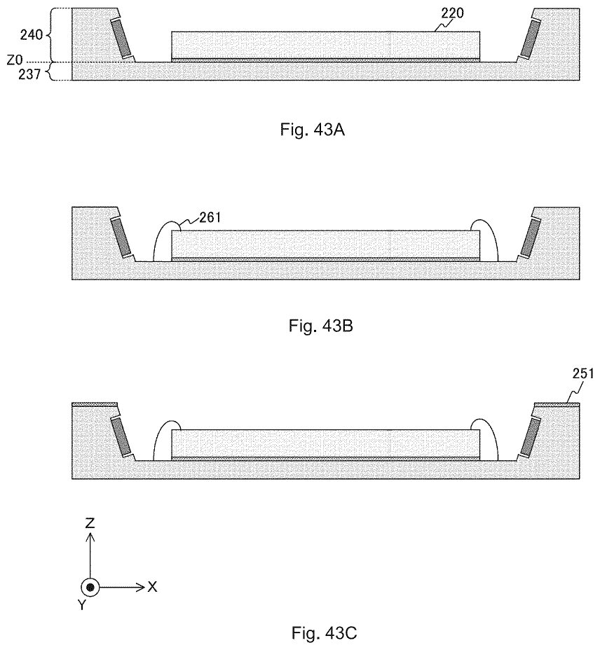

Then, as illustrated in FIG. 43a, the sensor chip 220 is bonded. Subsequently, as illustrated in FIG. 43b, the sensor chip 220 is connected by the wires 261. Subsequently, as illustrated in FIG. 43c, the seal material 251 is applied to the upper surface of the frame portion 240.

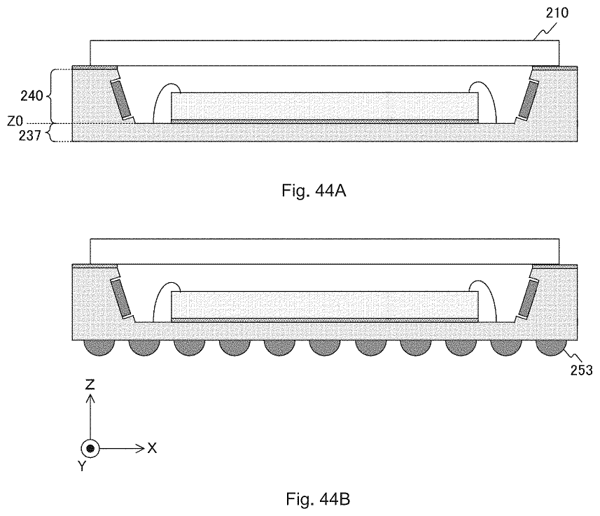

Then, as illustrated in FIG. 44a, the seal glass 210 is bonded. Subsequently, as illustrated in FIG. 44b, a predetermined number of solder balls 253 are formed on the lower surface of the wiring substrate 237, and the semiconductor package 200 is produced.

As described above, according to the ninth embodiment of the present technology, since the components 241 are disposed in the recessed portions on the side surfaces of the frame portion 240, interference between the component 241 and the wire 261 or the like can be avoided.

### 10. Tenth Embodiment

In the first embodiment described above, the components 241 are disposed on the side surfaces on the inner side of the frame portion 240, but in this configuration, when the size of the components 241 is large, the components 241 may interfere with the wires 261 or the sensor chip 220. The semiconductor package 200 according to the tenth embodiment is different from that according to the first embodiment in that the components 241 are disposed in the recessed portions formed on the side surfaces of the frame portion 240.

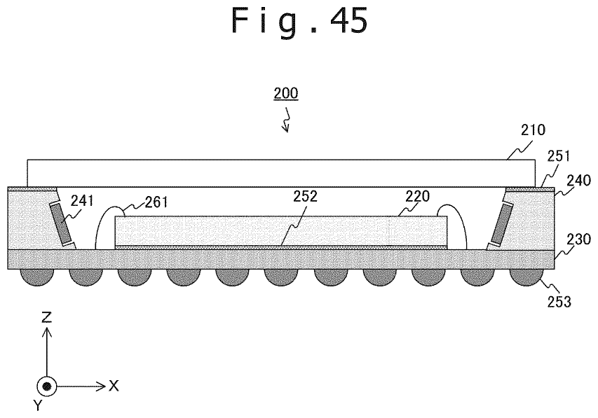

FIG. 45 is a cross-sectional view illustrating a configuration example of the semiconductor package 200 according to the tenth embodiment of the present technology. The semiconductor package 200 according to the tenth embodiment is different from that according to the first embodiment in that the recessed portions are formed on the side surfaces on the inner side of the frame portion 240 and the components 241 are disposed in the recessed portions. Note that recessed portions may be formed on the side surfaces on the outer side of the frame portion 240, and the components 241 may be disposed in the recessed portions.

As described above, by disposing the components 241 in the recessed portions on the side surfaces of the frame portion 240, interference between the component 241 and the wire 261 or the like can be avoided.

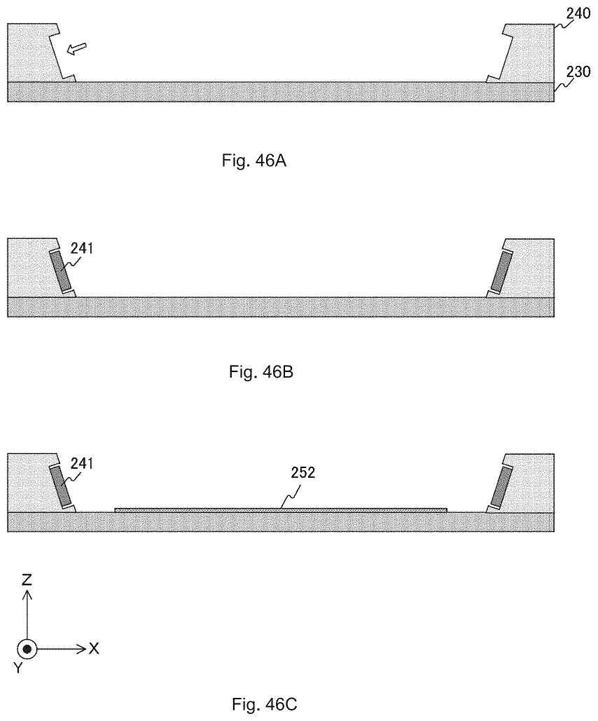

Next, a producing method for the semiconductor package 200 will be described with reference to FIGS. 46 to 48. As illustrated in FIG. 46a, the frame portion 240 with the recessed portions formed on the side surfaces is molded on the upper surface of the multilayer wiring substrate 230. An arrow in FIG. 46a indicates the recessed portion. Subsequently, as illustrated in FIG. 46b, the components 241 are disposed in the recessed portions. Subsequently, as illustrated in FIG. 46c, the die bond material 252 is applied to the upper surface of the multilayer wiring substrate 230.

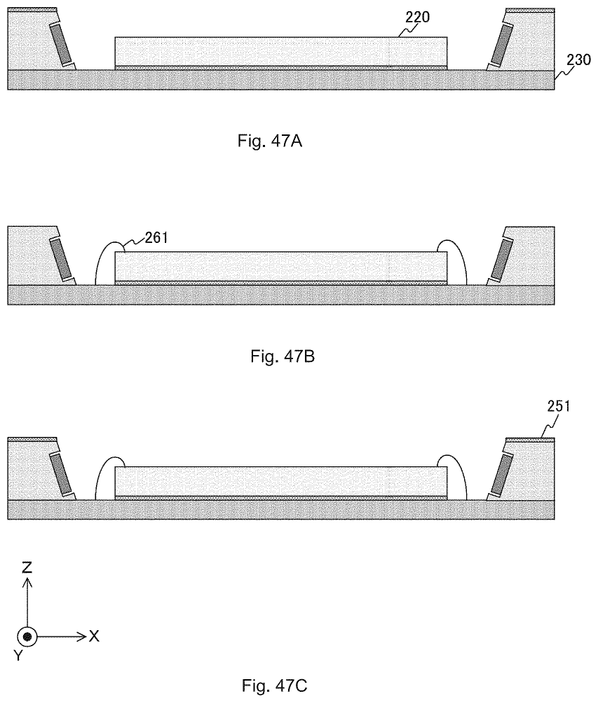

Then, as illustrated in FIG. 47a, the sensor chip 220 is bonded. Subsequently, as illustrated in FIG. 47b, the sensor chip 220 is connected by the wires 261. Subsequently, as illustrated in FIG. 47c, the seal material 251 is applied to the upper surface of the frame portion 240.

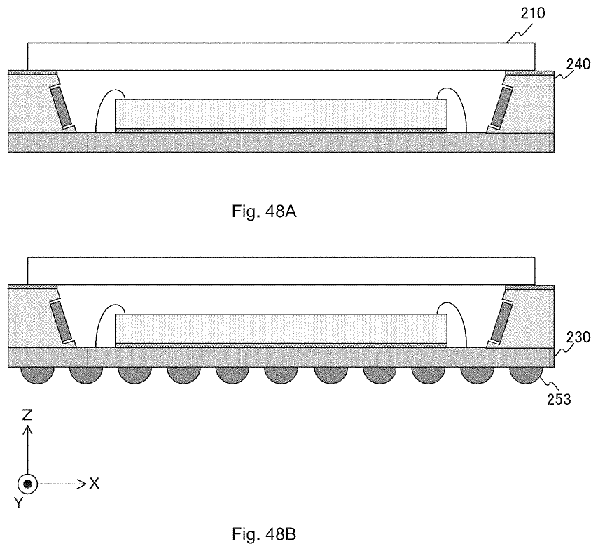

Then, as illustrated in FIG. 48a, the seal glass 210 is bonded. Subsequently, as illustrated in FIG. 48b, a predetermined number of solder balls 253 are formed on the lower surface of the multilayer wiring substrate 230, and the semiconductor package 200 is produced.

The tenth embodiment can be applied to each of the second, third, fourth, fifth, sixth, and seventh embodiments.

As described above, according to the tenth embodiment of the present technology, since the components 241 are disposed in the recessed portions on the side surfaces of the frame portion 240, interference between the component 241 and the wire 261 or the like can be avoided.

### 11. Example of Application to Mobile Body

The technology according to the present disclosure (present technology) can be applied to various products. For example, the technology according to the present disclosure may be implemented as a device mounted on any type of mobile bodies such as a vehicle, an electric vehicle, a hybrid electric vehicle, a motorcycle, a bicycle, a personal mobility, an airplane, a drone, a ship, and a robot.

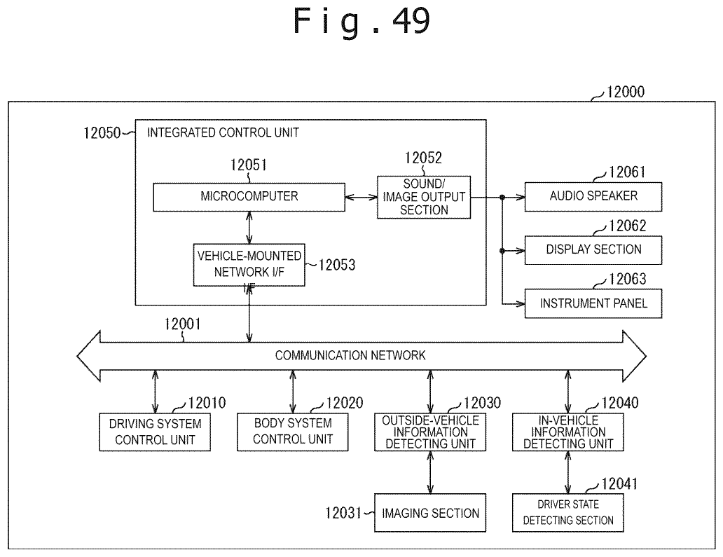

FIG. 49 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 49, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 49, an audio speaker 12061, a display section 12062, and an instrument panel 12063 are illustrated as the output device. The display section 12062 may, for example, include at least one of an on-board display and a head-up display.

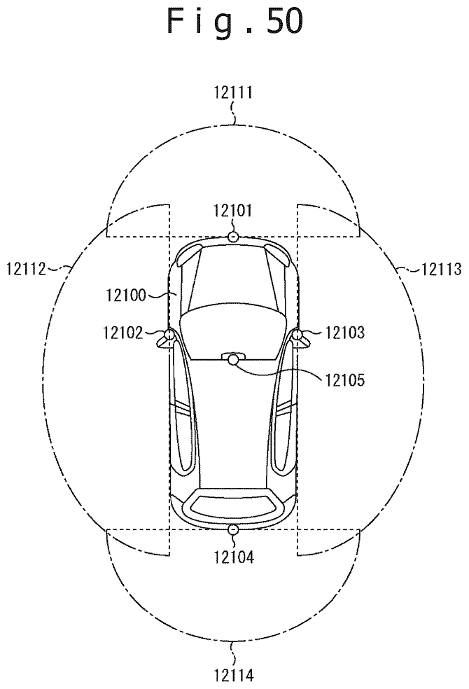

FIG. 50 is a diagram depicting an example of the installation position of the imaging section 12031.

In FIG. 50, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 50 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to the imaging section 12031 among the above-described configurations. Specifically, the electronic device 100 in FIG. 1 can be applied to the imaging section 12031. By applying the technology according to the present disclosure to the imaging section 12031, the number of components of the mounting substrate can be reduced.

Note that the above-described embodiments are examples for embodying the present technology, and the matters according to the embodiments and the matters specifying the invention in the scope of claims have correspondence relationships, respectively. Similarly, the matters specifying the invention in the scope of claims and the matters in the embodiments of the present technology to which the same names are given have correspondence relationships, respectively. However, the present technology is not limited to the embodiments, and can be embodied by applying various modifications to the embodiments without departing from the gist of the present technology.

Note that the effects described in the present specification are merely examples, and are not limited, and other effects may be obtained.

Note that the present technology may also have the following configurations.

(1) A semiconductor package including
a semiconductor substrate in which a frame portion is formed around a predetermined region in one surface of two surfaces when viewed from a direction perpendicular to the one surface,
a first semiconductor chip mounted in the predetermined region, and
a first component mounted on a surface of the frame portion.

(2) The semiconductor package according to (1), in which
the frame portion is an MID.

(3) The semiconductor package according to (1) or (2), in which
the first component is rectangular when viewed from a direction perpendicular to the surface of the frame portion, and
the first component is mounted at a position where a longitudinal direction of the first component is perpendicular or horizontal to an inner periphery of the frame portion.

(4) The semiconductor package according to any one of (1) to (3), further including
a solder resist applied to a surface of the MID.

(5) The semiconductor package according to any one of (1) to (4), in which
the frame portion covers the one surface of the semiconductor substrate and a side surface of the first semiconductor chip.

(6) The semiconductor package according to (5), in which
the frame portion further covers at least a part of the other surface of the two surfaces of the semiconductor substrate.

(7) The semiconductor package according to (5) or (6), further including
a solder ball disposed on the other surface of the semiconductor substrate.

(8) The semiconductor package according to any one of (1) to (7), further including
a glass,
a light-shielding film that shields a part of the glass from light, and
a second component with which a surface of the light-shielding film is provided.

(9) The semiconductor package according to (8), in which
the light-shielding film is an MID.

(10) The semiconductor package according to any one of (1) to (9), further including
a second semiconductor chip mounted around the frame portion.

(11) The semiconductor package according to any one of (1) to (10), in which
the frame portion and the semiconductor substrate are an MID.

(12) The semiconductor package according to any one of (1) to (11), in which
a recessed portion is formed on a side surface of the frame portion, and
the first component is mounted in the recessed portion.

(13) A producing method for a semiconductor package, including
a substrate producing procedure of preparing a semiconductor substrate in which a frame portion is formed around a predetermined region in one surface of two surfaces when viewed from a direction perpendicular to the one surface, and
a component mounting procedure of mounting a first component on a surface of the frame portion.

(14) The producing method for a semiconductor package, according to (13), further including
a cutting procedure of cutting a collective substrate including a plurality of semiconductor packages each provided with the first semiconductor chip, the frame portion, and the semiconductor substrate into individual semiconductor packages.

(15) The producing method for a semiconductor package, according to (13) or (14), in which
in the substrate producing procedure, the frame portion and the semiconductor substrate are connected to each other using solder.

(16) The producing method for a semiconductor package, according to (13) or (14), in which
in the substrate producing procedure, the frame portion and the semiconductor substrate are connected to each other by thermocompression bonding.

### REFERENCE SIGNS LIST

100 Electronic device
110 Optical section
120 Solid-state imaging element
130 Digital signal processing (DSP) circuit
140 Display section
150 Operation section
160 Bus
170 Frame memory
180 Storage section
190 Power supply section
200, 200-1, 200-2 Semiconductor package
210 Seal glass
220 Sensor chip
221 On-chip circuit
230 Multilayer wiring substrate
231 to 233, 242, 242-1, 242-2, 247, 248 Wiring line
234 On-board circuit
235, 253 Solder ball
236, 249 Electrode
237 Wiring substrate
240, 240-1, 240-2 Frame portion
241, 241-1 to 241-4, 246, 301 Component
243, 254 Pad
244 Solder resist
245 Light-shielding film
251 Seal material
252 Die bond material
261 Wire
270 Semiconductor chip
300 Mounting substrate
12031 Imaging section

1. A semiconductor package comprising:
a semiconductor substrate in which a frame portion is formed around a predetermined region in one surface of two surfaces when viewed from a direction perpendicular to the one surface;
a first semiconductor chip mounted in the predetermined region; and
a first component mounted on a surface of the frame portion.

2. The semiconductor package according to claim 1, wherein
the frame portion is a molded interconnect device (MID).

3. The semiconductor package according to claim 1, wherein
the first component is rectangular when viewed from a direction perpendicular to the surface of the frame portion, and
the first component is mounted at a position where a longitudinal direction of the first component is perpendicular or horizontal to an inner periphery of the frame portion.

4. The semiconductor package according to claim 1, further comprising:
a solder resist applied to a surface of the MID.

5. The semiconductor package according to claim 1, wherein
the frame portion covers the one surface of the semiconductor substrate and a side surface of the first semiconductor chip.

6. The semiconductor package according to claim 5, wherein
the frame portion further covers at least a part of the other surface of the two surfaces of the semiconductor substrate.

7. The semiconductor package according to claim 5, further comprising:
a solder ball disposed on the other surface of the semiconductor substrate.

8. The semiconductor package according to claim 1, further comprising:
glass;
a light-shielding film configured to shield a part of the glass from light; and
a second component with which a surface of the light-shielding film is provided.

9. The semiconductor package according to claim 8, wherein
the light-shielding film is an MID.

10. The semiconductor package according to claim 1, further comprising:
a second semiconductor chip mounted around the frame portion.

11. The semiconductor package according to claim 1, wherein
the frame portion and the semiconductor substrate are an MID.

12. The semiconductor package according to claim 1, wherein
a recessed portion is formed on a side surface of the frame portion, and
the first component is mounted in the recessed portion.

13. A producing method for a semiconductor package, comprising:
a substrate producing procedure of preparing a semiconductor substrate in which a frame portion is formed around a predetermined region in one surface of two surfaces when viewed from a direction perpendicular to the one surface; and
a component mounting procedure of mounting a first component on a surface of the frame portion.

14. The producing method for a semiconductor package, according to claim 13, further comprising:
a cutting procedure of cutting a collective substrate including a plurality of semiconductor packages each provided with the first semiconductor chip, the frame portion, and the semiconductor substrate into individual semiconductor packages.

15. The producing method for a semiconductor package, according to claim 13, wherein
in the substrate producing procedure, the frame portion and the semiconductor substrate are connected to each other using solder.

16. The producing method for a semiconductor package, according to claim 13, wherein
in the substrate producing procedure, the frame portion and the semiconductor substrate are connected to each other by thermocompression bonding.
